(19) United States
(12) Patent Application Publication
(10) Pub. No.: US 2024/0061384 A1
(43) Pub. Date: Feb. 22, 2024

(54) Resilience enhanced simulation method for container logistics supply chain system based on adaptive fuzzy double feedback

(71) Applicant: Shanghai Maritime University, Shanghai (CN)

(72) Inventors: Bowei Xu, Shanghai (CN); Weiting Liu, Shanghai (CN); Junjun Li, Shanghai (CN); Hailing Wang, Shanghai (CN); Tianmiao Gao, Shanghai (CN); Qiuju Xiong, Shanghai (CN); Wei Chen, Shanghai (CN)

(21) Appl. No.: 18/236,507

(22) Filed: Aug. 22, 2023

(30) Foreign Application Priority Data
Aug. 23, 2022 (CN) 202211009821.2

(51) Int. Cl. G05B 13/02; G06Q 10/08

(52) U.S. Cl. CPC G05B 13/0275; G06Q 10/08

(57) ABSTRACT

The present invention discloses a resilience-enhanced simulation method for container logistics supply chain based on adaptive fuzzy double feedback, specific steps comprising: applying a container logistics supply chain system to simulate the impact of adverse events; Designing a two-dimensional resilience index to measure the overall resilience of the container logistics supply chain system; Based on this simulation system, an adaptive fuzzy dual feedback control structure is established and a resilience enhanced method is proposed, so that the output of unfinished container operations affected by adverse events converge to zero quickly. By simulating the supply chain system under step demand, the effectiveness of the resilience enhanced control method of container logistics supply chain is verified. The results show that the method of the present invention significantly weakens the output response oscillation of the container logistics supply chain system, reduces the response time and enhances the system resilience.

### CROSS-REFERENCE TO RELATED APPLICATION

The subject application claims priority on Chinese patent application CN202211009821.2 filed on 2022 Aug. 23, the contents and subject matter thereof being incorporated herein by reference.

### FIELD OF INVENTION

The invention relates to the simulation of container logistics supply chain resilience, in particular to a resilience-enhanced simulation method of the container logistics supply chain based on adaptive fuzzy double feedback.

### BACKGROUND ART

The container logistics supply chain simulation is a service-oriented supply chain simulation with container logistics as the core, and it is an indispensable part of the international trade system. Container logistics supply chain simulation is challenging due to the daunting circumstances such capacity restrictions, port congestion, a lack of containers, a lack of space, a lack of ships, and delays in inland transportation as a result of the recurrent spread of unfavorable occurrences. The resilience operation of container logistics supply chain simulation has drawn a lot of interest from the government, business community, and general public as a result of unfavorable events.

Today, simulation technology is used in a wide range of industries, comprising engineering, health, transportation, the military, and more to forecast, analyze, and make choices by imitating real-world processes, behaviors, and systems. The accuracy and dependability of simulation can be improved with more powerful computation by processing larger amounts of data and more complicated models. In order to make simulations more thorough and comprehensive, multidisciplinary integration of information and methodologies is another being a where simulation technology is continually evolving.

The use of simulation technology allows for the resilience adjustment of parameters, the simulation of scenarios, and the realization of research into various container design systems and operation techniques. It provides a variety of test scenarios and data while simulating complicated environments and events. System simulation can be used to avoid the risks and expenses of genuine systems and lower the risk of supply chain simulation systems actually operating. By replicating system behavior at a lower cost than experimentation or testing on an actual system, simulation can aid in system design and optimization. It is possible to predict and evaluate in advance the performance and reliability of the system under various circumstances by simulating its operation.

Simulation models being approximate representations of actual systems, and the accuracy of the input data and presumptions will have a direct impact on the model's accuracy. Simulation technology still has some accuracy limitations. The reliability of the simulation findings still needs to be c being fully assessed and validated because it can only produce theoretical and virtual outcomes because it lacks real-world operation experience and environmental consideration. In addition, the modeling and parameter setting of complex systems being significant barriers to progress, and the integration of simulation technology and multi-science is inseparable from the assistance of knowledge in numerous domains.

### SUMMARY OF THE INVENTION

The object of the present invention is to provide a resilience enhanced simulation method for a container logistics supply chain based on adaptive fuzzy double feedback.

The resilience enhanced simulation method for a container logistics supply chain based on adaptive fuzzy double feedback simulates a container logistics supply chain system based on adaptive fuzzy double feedback, wherein the container logistics supply chain system comprises a multitude of container ships, a container port and a container freight station; the multitude of container ships, the container port and the container freight station coordinate for smooth transportation and transshipment of goods:
an upstream customer submitting a transportation order to a logistics service provider with an order request, a carrier transporting the shipper's goods to the container port by a container ship; the container ship loading and unloading a multitude of goods in the container port, upon arrival of the container ship at the container port, by means of a multitude of cranes, a multitude of stackers and a miscellaneous equipment in the container port; said loading and unloading is under constraint of minimized cargo detention time, actual arrival rate of the container, a waiting time of the container at the anchorage, a delay time of berth allocation, and a container operation time;
the container freight station is responsible for unloading the goods from the container ship, and in the freight station for temporary storage, distribution and reloading and miscellaneous operations; an inherent feature of the system is a certain time delay in the loading and unloading process, which is regarded as resulting from a difference between the container processing capacity and the container processing completion rate level in data processing; in a final step, according to the shipper's requests, distributing the multitude of goods in the multitude of containers to the end user or other destinations.

The present invention, on the basis of the afore-mentioned container logistics supply chain system, sets up a container logistics supply chain simulation system, which comprises a container pretreatment subsystem and a container operation subsystem to simulate the impact of adverse events. A two-dimensional resilience index is designed to measure the overall resilience of the container logistics supply chain simulation system in real time, and reveal the interaction mechanism between the internal elements of the system from the aspects of bearing capacity and resilience. The architecture of an adaptive fuzzy dual feedback control system is established, and a resilience enhanced simulation method for container logistics supply chain simulation is proposed. To characterize the simulation, the resilience enhanced simulation method for the container logistics supply chain based on adaptive fuzzy double feedback of the present invention inputs a non-negative unit step function waveform as an actual arrival rate of containers CARATE, and outputs a UCHR output waveform. Setting the UCHR output waveform as the control object, an adjustment time T_{UCHR} of the unfinished container operation volume of the container port and an adjustment time T_{FCPR} of the container port's preprocessing requirements being obtained for control, so as to realize the real-time update of the control parameters T_{UCHR} and T_{FCPR} embedded in the container logistics supply chain simulation system. The ultimate control goal is to make the UCHR waveform of the output unfinished container operation less affected and converge to 0 faster, and at the same time enhance the resilience of the system to optimize the control effect of the container port logistics supply chain simulation system, alleviate the impact of adverse events on the supply chain simulation system, and make the system stabilize as soon as possible. The influence of container preprocessing subsystem on supply chain simulation response and resilience is evaluated to verify the effectiveness of the container logistics supply chain resilience enhancement simulation method. Comp being d with the traditional method, the method of the present invention significantly weakens the oscillation of the container logistics supply chain simulation system, reduces the response time, and enhances the system resilience.

In order to achieve the above objectives, the present invention proposes the following technical solution:
Step 1, establishing a container logistics supply chain simulation system, comprising two subsystems: a container preprocessing subsystem CPS and a container handling sub system CHS.
the container pretreatment subsystem CPS comprises:
a container arrival pretreatment unit, an expected pretreatment time unit, an adjustment time unit and an allocation delay strategy unit;
the container handling subsystem CHS comprises:
a container handling requirement forecasting unit, a desired delay time unit, a first adjustment time unit, a second adjustment time unit and a container handling delay strategy unit;
a detailed description of each module is described as below:
the container arrival preprocessing unit inputting the non-negative unit step function waveform as the actual arrival rate of the container CARATE, and performing a product operation through the built-in container arrival preprocessing function to output the average container arrival rate AVRATE;
the expected pretreatment time unit setting the average container arrival rate AVRATE as input, and multiplying with the expected lead period E of the built-in pre-processing subsystem;
the expected container pretreatment requirement DFCPR subtracting the completed container pretreatment requirement FCPR obtained by the integral unit to obtain the container pretreatment demand difference EFCPR;
the adjustment time unit setting the completed container preprocessing requirement difference EFCPR as input, and dividing the built-in adjustment time parameter TFCPR, and obtaining the operation result as the adjustment amount FCPRadj of FCPR;
the adjustment amount of FCPRadj and the average container arrival rate AVRATE being added to the output PCPR for the planned container pretreatment requirement;
the allocation delay strategy unit, setting the planned container preprocessing demand PCPR as input, and the built-in allocation delay strategy function

$$\frac{1}{{T}_{P 1} \cdot s + 1}$$

to do the product operation, the operation result is the allocation completion amount COMRATE1, COMRATE1 as the input of the container operation demand forecasting unit, and the container operation completion capacity COMRATE is subtracted, COMRATE1 minus the container operation completion capacity COMRATE; T_{P1} is the allocation delay time, and s is the complex frequency domain variable of the Laplace transform, wherein, s=σ+jw is a frequency in the plural form, where the real part σ is constant positive, and the imaginary part jw can be positive, negative, and zero;
the container operation demand forecasting unit multiplies the input container operation demand ACHR with the built-in container operation demand forecasting function

$$\frac{1}{{T}_{A} \cdot s + 1}$$

to output the average container operation demand AVCHR; T_{A} is the time constant of container operation demand forecasting;
the expected delay time unit connecting with the container operation demand forecasting unit 5 to obtain the average container operation demand AVCHR as input, and the built-in expected delay time parameter TQ is multiplied to output the expected container operation demand DCHIP;
subtracting the container operation requirement CHIP obtained by the first integral unit from the container operation requirement in processing DCHIP that is expected to be processed, and outputting the difference in container operation demand in processing ECHIP;
the first adjustment time unit, with ECHIP as input, and the built-in first adjustment time parameter TCHIP to do division operation, ECHIP dividing by TCHIP operation result is CHIPadj;
the second adjustment time unit setting the unfinished container operation volume UCHR output by the model as input, and dividing the built-in second adjustment time TUCHR, and dividing UCHR by TUCHR to obtain the operation result of UCHRadj; the adjustment amount of UCHRadj and the adjustment amount of CHIP CHIPadj and the AVCHR obtained by the container operation demand forecasting unit being added to the sum of the three outputs for the container operation capacity PCHR;
the container operation delay strategy unit setting the container operation capacity PCHR as the input, and the built-in container operation delay strategy function to do the product operation, and the output is the container operation completion capacity COMRATE;
obtaining the container operation capacity PCHR and the container operation completion capacity RATE to do the subtraction operation, the operation result is output to the first integration unit, and the first integration unit outputting the container operation requirements in processing CHIP;
obtaining the container operation requirement ACHR, subtracting the container operation completion capacity COMRATE, and outputting the operation result to the second integration unit.
the connections between the units being described as below:
the container arrival pretreatment unit outputs the average container arrival rate AVRATE;
the expected pretreatment time unit connecting with the container arrival pretreatment unit for output, and the expected completion of the container pretreatment demand DFCPR is obtained;
the integral unit obtaining the completed container preprocessing requirements FCPR the adjustment time unit receiving the output of the container arriving at the pretreatment unit connecting with the expected pretreatment time unit, and outputting the adjustment amount FCPRadj of FCPR;
the delay strategy unit is assigned to receive the output of the container arrival preprocessing unit and the adjustment time unit, and obtaining the container operation completion amount COMRATE1, and using it as the input of the container handing sub system;
the integration unit receiving the output of the allocation delay strategy unit to obtain the container preprocessing requirement FCPR;
the container operation demand forecasting unit outputting the average container operation demand AVCHR;
the expected delay time unit and the container operation demand forecasting unit being connecting for output to obtain the expected processing container operation demand DCHIP;
the first integral unit capturing the CHIP of the container operation requirements in process;
the first adjustment time unit receiving the output of the container operation demand forecasting unit and the expected delay time unit connecting, and outputting the adjustment amount CHIPadj of CHIP;
the second adjustment time unit receiving the unfinished container operation volume UCHR outputting by the model, and obtaining the adjustment amount UCHRadj of UCHR;
the container operation delay strategy unit receiving the output of the first adjustment time unit and the second adjustment time unit and the container operation demand forecasting unit, and outputting the container operation completion capacity COMRATE.
the second integral unit receiving the unfinished container operation volume UCHR in the container port, and finally obtaining the UCHR output waveform of the container operation subsystem.
Step 2, defining a state space of the container logistics supply chain system, and obtaining a corresponding transfer function;

Specific steps comprise:
Step 2.1, determining the transfer functions of COMRATE1 and a planned container pretreatment demand PCPR in the subsystem CPS relative to the actual arrival rate of the container;
in the subsystem CPS, the variable integral of the difference between the container allocation completion rate COMRATE1 and the actual container arrival rate CARATE over time is taken as the pretreatment completion rate FCPR of the CPS in the container pretreatment stage;

FCPR(t)=∫(COMRATE₁(t)−CARATE(t))dt (1)
then, the planned container preprocessing requirement PCPR and the allocation delay strategy function

$$\frac{1}{{T}_{P 1} s + 1}$$

being multiplied to obtain the allocation completion rate COMRATE1 expressed by the indefinite integral, wherein decomposed into 1/S and 1/T_{P1} series when calculating

$$\frac{1}{{T}_{P 1} s + 1} ,$$

and adding a feedback loop;

$${COMRATE}_{1} ( t ) = \frac{1}{{T}_{p 1}} \int ( PCPR ( t ) - {COMRATE}_{1} ( t ) ) dt \qquad ( 2 )$$

the actual container arrival rate CARATE and the container operation delay strategy function

$$\frac{1}{{T}_{P} s + 1}$$

being multiplied to obtain the average container arrival rate AVRATE represented by the indefinite integral, wherein decomposed into 1/S and 1/T_{P} series when calculating, and adding a feedback loop

$$AVRATE ( t ) = \frac{1}{{T}_{WAIT}} \int ( CARATE ( t ) - AVRATE ( t ) ) dt \qquad ( 3 )$$

the container logistics supply chain simulation system selecting FCPR=x₁, ∫(PCPR(t)−COMRATE₁(t))dt=x₂, AVRATE·T_{WAIT}=x₃, where x₁ representing the completed container pretreatment requirement, x₂ representing the integral of the difference between the planned container pre-processing requirement and the allocated completion volume, and x₃ representing the average container actual arrival rate status, then:

$${\dot{x}}_{1} = \frac{1}{{T}_{p 1}} {x}_{2} - CARATE \qquad ( 4 )$$

$${\dot{x}}_{2} = - \frac{1}{{T}_{FCPR}} {x}_{1} - \frac{1}{{T}_{p 1}} {x}_{2} + \frac{1}{{T}_{WAIT}} ( 1 + E ) {x}_{3} \qquad ( 5 )$$

$${\dot{x}}_{3} = - \frac{1}{{T}_{WAIT}} {x}_{3} + CARATE \qquad ( 6 )$$

the preset container pretreatment requirement PCPR of the simulation is expressed as:

$$PCPR = - \frac{1}{{T}_{FCPR}} {x}_{1} + \frac{1}{{T}_{WAIT}} ( 1 + E ) {x}_{3} \qquad ( 7 )$$

the continuous closed-loop state space of CPS in the container pretreatment stage is expressed as:

$$\dot{x} = [ \begin{matrix}0 & \frac{1}{{T}_{p 1}} & 0 \\ - \frac{1}{{T}_{i}} & - \frac{1}{{T}_{p}} & \frac{1}{{T}_{WAIT}} ( 1 + E ) \\ 0 & 0 & - \frac{1}{{T}_{WAIT}}\end{matrix} ] x + [ \begin{matrix}- 1 \\ 0 \\ 1\end{matrix} ] CARATE \qquad ( 8 )$$

the transfer function of the allocation completion amount COMRATE1 and the planned container pretreatment demand PCPR relative to the actual arrival rate of the container CARATE in the container pretreatment subsystem CPS is:

$$\frac{{COMRATE}_{1}}{CARATE} = \frac{( {T}_{FCPR} + {T}_{WAIT} + E ) s + 1}{\begin{matrix}{T}_{FCPR} {T}_{p 1} {T}_{WAIT} [ 1 / {T}_{FCPR} {T}_{p 1} + 1 / {T}_{p 1} s + {s}^{2} ] \\ ( s + 1 / {T}_{WAIT} )\end{matrix}} \qquad ( 9 )$$

$$\frac{PCPR}{CARATE} = \frac{\begin{matrix}( {T}_{FCPR} {T}_{p 1} + {T}_{p 1} W + {T}_{p 1} {T}_{WAIT} ) {s}^{2} + \\ ( {T}_{FCPR} + E + {T}_{p 1} + {T}_{WAIT} ) s + 1\end{matrix}}{\begin{matrix}{T}_{FCPR} {T}_{p 1} {T}_{WAIT} [ 1 / {T}_{FCPR} {T}_{p 1} + 1 / {T}_{p 1} s + {s}^{2} ] \\ ( s + 1 / {T}_{WAIT} )\end{matrix}} \qquad ( 10 )$$

Step 2.2, determining the transfer function of the unfinished container operation volume UCHR and the container operation capacity PCHR relative to the container operation demand ACHR respectively in the second subsystem CHS;
in the subsystem CHS, the difference between the container operation requirement ACHR and the container operation completion capacity COMRATE is taken as the indefinite integral over time as the uncompleted container operation volume UCHR in the simulation;

UCHR(t)=∫(ACHR(t)−COMRATE(t))dt (11)
the difference between the container operation capacity PCHR and the container operation completion capacity CARRIER is taken as the variable integral over time as the container operation demand CHIP in processing;

CHIP(t)=∫(PCHR(t)−COMRATE(t))dt (12)
the container operation demand ACHR and the container operation demand forecasting function

$$\frac{1}{{T}_{A} \cdot s + 1}$$

being multiplied to obtain the average container operation demand AVCHR, wherein decomposed into 1/S and 1/T_{A} series when calculating

$$\frac{1}{{T}_{A} \cdot s + 1} ,$$

and a feedback loop is added from 1/T_{A},

$$AVCHR ( t ) = \frac{1}{{T}_{A}} \int ( ACHR ( t ) - AVCHR ( t ) ) dt \qquad ( 13 )$$

the container logistics supply chain simulation system selecting UCHR=x₄, CHIP=x₅, AVCHR·TA=x₆, where x4 and x5 representing the outstanding container operation volume and the container operation demand in processing, respectively, and x6 representing the average container operation demand, then:

$${\dot{x}}_{4} = \frac{1}{{T}_{p}} {x}_{5} + ACHR \qquad ( 14 )$$

$${\dot{x}}_{5} = \frac{1}{{T}_{UCHR}} {x}_{4} - ( \frac{1}{{T}_{p}} + \frac{1}{{T}_{CHIP}} ) {x}_{5} + ( \frac{1}{{T}_{A}} + \frac{{T}_{Q}}{{T}_{CHIP} {T}_{A}} ) {x}_{6} \qquad ( 15 )$$

$${\dot{x}}_{6} = \frac{1}{{T}_{A}} {x}_{6} + ACHR \qquad ( 16 )$$

the PCHR is:

$$PCHR = \frac{1}{{T}_{UCHR}} {x}_{4} - \frac{1}{{T}_{CHTP}} {x}_{5} + ( \frac{1}{{T}_{A}} + \frac{{T}_{Q}}{{T}_{CHIP} {T}_{A}} ) {x}_{6} \qquad ( 17 )$$

the transfer function of the unfinished container operation volume UCHR and the container operation capacity PCHR relative to the container operation requirement ACHR in the container operation subsystem CHS is:

$$\frac{UCHR}{ACHR} = \frac{( {T}_{P} + {T}_{CHIP} + {T}_{CHIP} {T}_{P} s ) ( 1 + {T}_{A} s ) - {T}_{Q} - {T}_{CHIP}}{\begin{matrix}{T}_{CHIP} {T}_{P} {T}_{A} [ 1 / {T}_{UCHR} {T}_{P} + ( 1 / {T}_{CHIP} + 1 / {T}_{P} ) s + {s}^{2} ] \\ ( s + 1 / {T}_{A} )\end{matrix}} \qquad ( 18 )$$

$$\frac{PCHR}{ACHR} = \frac{( 1 + {T}_{P} s ) [ {T}_{CHIP} + ( {T}_{CHIP} {T}_{A} - {T}_{U} {T}_{Q} - {T}_{UCHR} {T}_{CHIP} ) s ]}{\begin{matrix}{T}_{UCHR} {T}_{CHIP} {T}_{P} {T}_{A} \\ [ 1 / {T}_{UCHR} {T}_{P} + ( 1 / {T}_{CHIP} + 1 / {T}_{P} ) s + {s}^{2} ] ( s + 1 / {T}_{A} )\end{matrix}} \qquad ( 19 )$$

Step 2.3, determining transfer function between the unfinished container operation volume UCHR and the container operation capacity PCHR in the CHS relative to the actual arrival rate CARATE of the input container in the CPS, respectively;
the transfer function of the unfinished container operation volume UCHR and the container operation capacity PCHR relative to the actual arrival rate of the input container in the upper subsystem CARATE is as follows:

$$\frac{UCHR}{CARATE} = \frac{{COMRATE}_{1}}{CARATE} \cdot \frac{UCHR}{ACHR} \qquad ( 20 )$$

$$\frac{PCHR}{CARATE} = \frac{{COMRATE}_{1}}{CARATE} \cdot \frac{PCHR}{ACHR} \qquad ( 21 )$$

Step 2.4, after the transfer function is derived, the actual arrival rate CARATE of the container input in the first stage is represented as a non-negative unit step function waveform, and the final response state

$${lim}_{t \to ∞} uchr ( t )$$

is obtained according to the final value theorem

$${lim}_{t \to ∞} uchr ( t ) = {lim}_{s \to 0} sUCHR ( s ) .$$

the state space of the container logistics supply chain simulation system is described as:

$$\dot{x} = ( \begin{matrix}A & 0 \\ 0 & B\end{matrix} ) x + ( \begin{matrix}- 1 \\ 0 \\ 1 \\ 0 \\ 0 \\ 0\end{matrix} ) CARATE + ( \begin{matrix}0 \\ 0 \\ 0 \\ 1 \\ 0 \\ 1\end{matrix} ) ACHR \qquad ( 22 )$$

$$( \begin{matrix}PCPR \\ FCPR \\ {COMRATE}_{1} \\ PCHR \\ UCHR \\ CHIP\end{matrix} ) = Bx$$

$$Wherein ,$$

$$( 23 )$$

$$A = ( \begin{matrix}0 & \frac{1}{{T}_{p 1}} & 0 & & & \\ - \frac{1}{{T}_{i}} & - \frac{1}{{T}_{p}} & \frac{1}{{T}_{WAIT}} ( 1 + E ) & & & \\ 0 & 0 & - \frac{1}{{T}_{WAIT}} & & & \\ & & & 0 & \frac{1}{{T}_{p}} & 0 \\ & & & \frac{1}{{T}_{UCHR}} & - ( \frac{1}{{T}_{p}} + \frac{1}{{T}_{CHIP}} ) & ( \frac{1}{{T}_{A}} + \frac{{T}_{Q}}{{T}_{CHIP} {T}_{A}} ) \\ & & & 0 & 0 & - \frac{1}{{T}_{A}}\end{matrix} )$$

$$( 24 )$$

$$B = ( \begin{matrix}- \frac{1}{{T}_{FCPR}} & 0 & \frac{1}{{T}_{WAIT}} ( 1 + E ) & & & \\ 1 & 0 & 0 & & & \\ 0 & \frac{1}{{T}_{p 1}} & 0 & & & \\ & & & \frac{1}{{T}_{UCHR}} & - \frac{1}{{T}_{CHIP}} & ( \frac{1}{{T}_{A}} + \frac{{T}_{Q}}{{T}_{CHIP} {T}_{A}} ) \\ & & & 1 & 0 & 0 \\ & & & 0 & 1 & 0\end{matrix} )$$

when the actual container arrival rate CARATE input by the simulation subsystem CPS is a unit step signal, the final response of the model is obtained according to the final value theorem:

$${lim}_{s \to 0} s \cdot \frac{UCHR}{CARATE} = \frac{{T}_{UCHR} ( {T}_{P} - {T}_{Q} )}{{T}_{CHIP}} \qquad ( 25 )$$

$${lim}_{s \to 0} s \cdot \frac{PCHR}{CARATE} = 1 \qquad ( 26 )$$

from equation (25), uchr (∞) depending on T_{UCHR} [symbol] T_{CHIP} [symbol] T_{P} and T_{Q}, when T_{P}=T_{Q}, uchr(∞)=0;
uchr(t) is the Laplace transform of UCHR, and s is the complex frequency domain variable of the Laplace transform;
Step 3, designing a two-dimensional indicator R to measure the resilience of the container logistics supply chain:

R=\sqrt{FL² RE²} (29)

FL=[∫₀^{∞}(PCHR(t))²dt/∫₀^{∞}(CARATE(t))²dt] (30)

RE=\sqrt{α[ITAE_{UCHR}]²+β[ITAE_{FCPR}]²} (31)

ITAE_{UCHR}=∫₀^{∞}t|E_{UCHR}|dt (32)

ITAE_{FCPR}=∫₀^{∞}t|E_{FCPR}|dt (33)
wherein, FL is used to characterize the fluctuation of the actual arrival rate of containers in the container pretreatment subsystem CPS when CARATE is input, and the fluctuation of the container operation capacity PCHR in the container operation subsystem CHS relative to the actual arrival rate of the container input container in the CPS subsystem, the smaller the fluctuation, the more accurate the response ability to the input of the CPS subsystem, and the higher the stability of the container logistics supply chain system. the calculation of FL comprehensively considering the system status of the CHS subsystem and the system input of the CPS subsystem, reflecting the bearing capacity of the container logistics supply chain system under the impact of adverse events, RE integrating the deviation value of the response of the two subsystems of the container logistics supply chain system as the deviation of the overall system; FL and RE reflecting the affordability and resilience of the container logistics supply chain system to a certain extent, but FL is biased towards the fluctuation degree within the container logistics supply chain system, and RE is biased towards the deviation of the output of the container logistics supply chain system, representing the degree of recovery under the influence of adverse events, FL and RE representing the bearing capacity and resilience of the supply chain system respectively, the smaller the internal fluctuation of the system, the stronger the bearing capacity, the smaller the degree of output deviation, and the stronger the resilience; ITAE_{UCHR} and ITAE_{FCPR} representing the accumulation of deviations of UCHR and FCPR with time, respectively; the smaller the values of ITAE_{UCHR} and ITAE_{FCPR}, the better the response and recovery ability of the system;
α and β being set as the proportional coefficients to make the orders of magnitude of ITAE_{UCHR} and ITAE_{FCPR} coordinate with FL; therefore, for the resilience index R, smaller R representing the better performance of the system; in formula (32-33), E_{UCHR} representing the deviation between the actual value of UCHR and the input actual container arrive rate CARATE, E_{FCPR} representing the deviation between the actual value of FCPR and the input actual container arrive rate CARATE; different from EFCPR, EFCPR being the difference of the finished container pretreatment requirement, representing the deviation between the desired value of FCPR DFCPR and FCPR; E_{UCHR}=uchr(t)−uchr(∞), E_{FCPR}=fcpr(t)−fcpr(∞); it can be obtained from Equation (25) that

$$uchr ( ∞ ) = {T}_{UCHR} ( {T}_{P} - {T}_{Q} ) / {T}_{CHIP} ;$$

$$fcpr ( ∞ ) = {lim}_{s \to 0} s \cdot FCPR / CARATE = 1 ;$$

Step 4, based on the container preprocessing requirements FCPR and the container port's unfinished container workload UCHR, two feedback paths between the adaptive fuzzy control and the container logistics supply chain simulation system being constructed, and the adaptive fuzzy double feedback control structure is established; establishing an adaptive fuzzy double feedback control method comprising one-level fuzzy logic control and two-level adaptive fuzzy logic control, the specific steps comprising:
Step 4.1, establishing a first first-level fuzzy logic syste, setting the deviation e₁ between the actual container arrive rate CARATE and the finished container pretreatment requirement FCPR and the deviation change rate ec₁ as the inputs of the fisrt first-level fuzzy logic system, further adjusting T_{FCPR} by controlling the change of smoothing coefficient α₁, feeding the updated FCPR back to the two-subsystem container logistics supply chain system;
Step 4.2, establishing a second first-level fuzzy logic system, setting the deviation e₂ between the actual container arrive rate CARATE and the unfinished container handling requirement UCHR and the deviation change rate ec₂ as the inputs of the second first-level fuzzy logic system, further adjusting T_{UCHR} by controlling the change of smoothing coefficient α₂, and feeding the updated UCHR back to the two-subsystem container logistics supply chain system;
Step 4.3, establishing a second-level adaptive fuzzy logic system; K₁ [symbol] K₂ and K₃ [symbol] K₄ being quantification factors of fuzzy inference inputs of first second-level fuzzy logic system and second second-level fuzzy logic system respectively, wherein the error quantification factor and error change rate quantification factor of the first fuzzy logic system being K₁, K₂ respectively, and the error quantification factor and error change rate quantification factor of the second fuzzy logic system being K₃ and K₄, respectively; adjusting the quantification factors online through a second-level adaptive fuzzy logic system; when the deviation is large, the main adaptive task is to eliminate the deviation, while when the deviation is small, the supply chain system is close to the steady state and the main adaptive task is to quickly adapt to changes of the external environment;
Step 4.4, designing the control rules of the first-level fuzzy logic system; for the first first-level fuzzy logic system and the second first-level fuzzy logic system, extracting the deviation e₁ and the deviation change rate e₁ between the actual container arrive rate CARATE and the finished container pretreatment requirement FCPR at the kth moment of the two-subsystem container logistics supply chain system, as well as the deviation e₂ and the deviation change rate ec₂ between the actual container arrive rate CARATE at the kth moment and the container port unfinished container handling requirement UCHR, setting e₁, ec₁ and e₂, ec₂ as the inputs of the first first-level fuzzy logic system and the second first-level fuzzy logic system respectively; defining the fuzzy subsets of the first-level fuzzy logic system as {VS(very small), S(small), RS(relatively small), M(medium), RB(relatively big), B(big), VB(very big)}, and the fuzzy domain as {0, 1}; the membership function of input and output adopting uniformly distributed trigonometric function; according to the input and output requirements, the first-level fuzzy control rules being set as follows:

| | e | | | | | | |
|---|---|---|---|---|---|---|---|
| ec | VS | S | RS | M | RB | B | VB |
| VS | M | RS | RS | S | S | VS | VS |
| S | RB | M | RS | RS | S | S | VS |
| RS | RB | RB | M | RS | RS | S | S |
| M | B | RB | RB | M | RS | RS | S |
| RB | B | B | RB | RB | M | RS | RS |
| B | VB | B | B | RB | RB | M | RS |
| VB | VB | VB | B | B | RB | RB | M |

wherein e is the deviation and ec is the deviation change rate; when the deviation change rate ec₁ and ec₂ being relatively large, increasing the smoothing coefficient α₂ to alleviate the rapid change of the supply chain system under the influence of adverse events, while when the deviation e₁ and e₂ being large, reducing the smoothing coefficient α₁ [symbol] β₂ to make the deviation e₁ and e₂ return to a more ideal state;
Step 5, designing the control rules of the second-level adaptive fuzzy logic system; setting quantization factors K₁, K₂, K₃ and K₄ as control objects; based on the update of smoothing coefficients, further updating the control effect of quantization factors on first-level fuzzy logic system, that is, when the input deviations e₁ and e₂ of two first-level fuzzy logic systems being large, the main task of adaptive is to increase the error quantization factors K₁ and K₃ to eliminate the deviation, and when the input deviation is small and the input deviation change rate ec₁ and ec₂ being large, the supply chain system is close to the steady state, making the main adaptive task is to increase the error change rate quantization factors K₂ and K₄ to make the system stable as soon as possible, so as to achieve the purpose of adaptive adjustment by using quantization factors;
setting the membership function corresponding to the input of the second-level adaptive fuzzy logic system as uniformly distributed trigonometric functions; setting the fuzzy subset as {NB(negative big), NM(negative middle), NS(negative small), Z(zero), PS(positive small), PM(positive middle), PB(positive big)}; defining the fuzzy subset of the output of adaptive fuzzy logic as {VS(very small), S(small), M(medium), B(big), VB(very big)}, the basic domain is {0, 1}; setting the second-level adaptive fuzzy control rules as:

| | e | | | | | | |
|---|---|---|---|---|---|---|---|
| ec | NB | NM | NS | Z | PS | PM | PB |
| NB | B | B | M | VS | S | M | B |
| NM | B | B | M | S | S | B | B |
| NS | VB | B | M | M | M | B | VB |
| Z | VB | B | B | M | B | B | VB |
| PS | VB | B | M | M | M | B | VB |
| PM | B | B | M | S | M | B | B |
| PB | B | M | S | VS | S | M | B |

when both the deviation e and the deviation change rate ec being close to zero (Z), the quantization factors K₁, K₂, K₃ and K₄ of the two inputs of the control fuzzy system having the same proportion; when the deviation e is close to 0 value and the deviation change rate ec tending to be large or small, the proportion of adjusting e is the smallest and that of ec is the largest; when the deviation rate ec is close to 0 value and the deviation e is large or small, adjusting the proportion of e to the maximum to achieve the purpose of adaptive adjustment.
Step 5, using the container logistics supply chain system resilience measurement method provided in Step 3 and the adaptive fuzzy double feedback control method provided in Step 4, verifying the effectiveness of the simulation method under the influence of adverse events; the steps comprising
Step 5.1, setting the average waiting time T_{WAIT} as 3˜24 cycles, setting the rated value of T_{WAIT} as 6 cycles; setting the FCPR adjustment time constant T_{FCPR} as 2˜16 cycles, setting the rated value of T_{FCPR} as 4 cycles; setting the average container port handling time T_{P} as 2˜6 cycles, setting the rated value of T_{P} as 4 cycles; setting the desired pretreatment period E as 1; setting the container handling forecasting requirement time constant T_{A}=6, T_{Q}=T_{P}=4; setting the allocation delay time T_{P1} as 0.5˜2 cycles, setting the rated value of T_{P1} as 1 cycle; simulating the influence of time constants T_{WAIT} and T_{FCPR} in the container pretreatment system on the response UCHR, CHIP and PCHR and resilience of the two-subsystem container logistics supply chain system, and analyzing of two-dimensional mechanism of resilience R;
Step 5.2, setting UCHR and R as the response performance and resilience performance of the two-subsystem container logistics supply chain system, and T_{WAIT} as the main variable of the supply chain system; simulating and verifying the effectiveness of the resilience-enhancement control method of the container logistics supply chain based on adaptive fuzzy double feedback in increasing UCHR stability and shortening UCHR stability time, and the action mechanism of affordability and recovery ability on resilience under the resilience-enhancement control method of container logistics supply chain based on adaptive fuzzy double feedback is obtained; T_{A}, T_{P}, T_{Q}, E, T_{P1}, T_{WAIT}, T_{FCPR}, T_{CHIP}, T_{UCHR} being all positive numbers.

### BRIEF DESCRIPTION OF DRAWINGS

FIG. 1 is a simplified container logistics supply chain system of the resilience-enhancement control method of the container logistics supply chain based on adaptive fuzzy double feedback of the present invention.

FIG. 2 is a flowchart of the resilience-enhancement simulation method of the container logistics supply chain based on adaptive fuzzy double feedback of the present invention.

FIG. 3 is a schematic diagram of the overall structure of the two-level container logistics supply chain system of the resilience-enhancement control method of the container logistics supply chain based on adaptive fuzzy double feedback of the present invention.

FIG. 4 is a block diagram of the resilience-enhancement control method of the container logistics supply chain based on adaptive fuzzy double feedback of the present invention.

FIG. 5 is the input-output rules of one-level fuzzy logic control structure of the present invention.

FIG. 6 is the membership function corresponding to the output of the two-level adaptive fuzzy logic control structure of the present invention.

FIG. 7 is the input-output rules of the two-level adaptive fuzzy logic control structure of the present invention.

FIG. 8 is the impact of T_{WAIT} on the response of container logistics supply chain of the present invention.

FIG. 9 is the impact of T_{FCPR} on the response of container logistics supply chain of the present invention.

FIG. 10 is the impact of T_{WAIT} and T_{FCPR} on the resilience of container logistics supply chain of the present invention.

FIG. 11 is the three-dimensional grid, Contour line and two-dimensional trajectory of R of the present invention.

FIG. 12 is the comparison of container logistics supply chain response and resilience under three control methods of the present invention.

FIG. 13 is the resilience decomposition diagram of the container logistics supply chain under the present invention method of the present invention.

1 stands for the container arrival pretreatment unit; 2 stands for the expected pretreatment time unit; 3 stands for the adjustment time unit; 4 stands for the allocation delay strategy unit; 5 stands for the container handling requirement forecasting unit; 6 stands for the desired delay time unit; 7 stands for the first adjustment time unit; 8 stands for the second adjustment time unit; 9 stands for the container handling delay strategy unit.

### EMBODIMENTS

The following is a detailed explanation of the preferred specific embodiment, in conjunction with the accompanying drawings, to further elaborate on the present invention.

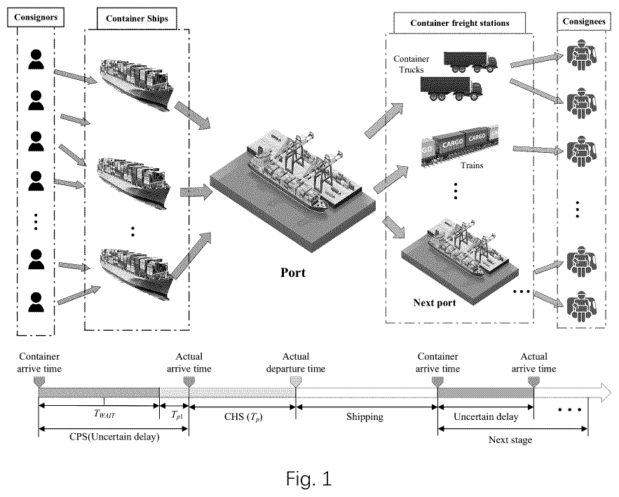

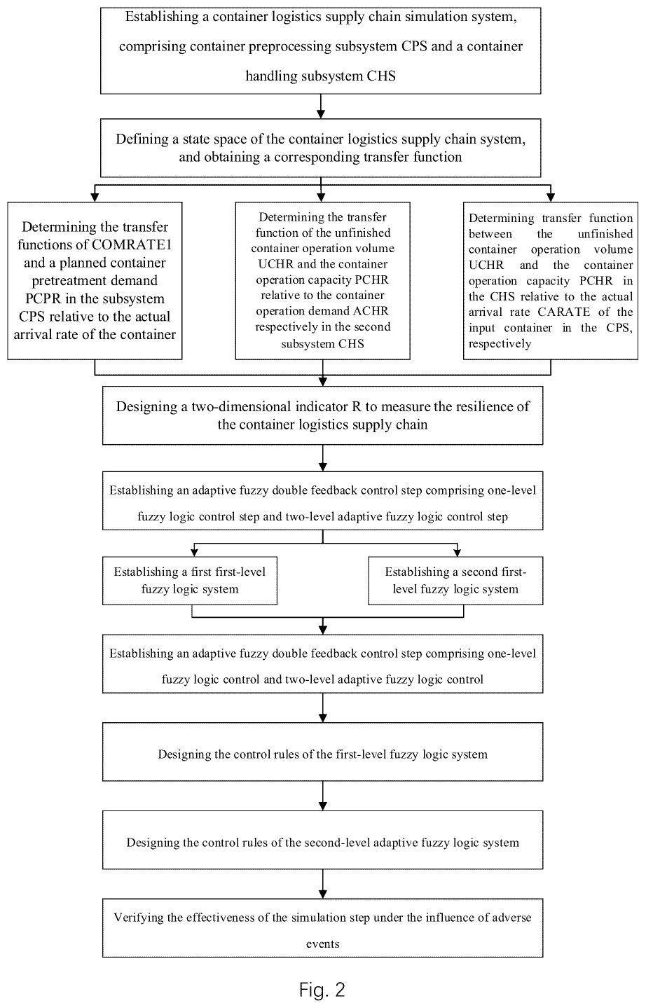

The specific working principle of the container logistics supply chain simulation system provided in the present invention is as follows:
A resilience enhanced simulation method for container logistics supply chain system based on adaptive fuzzy double feedback, wherein, based on an actual container logistics supply chain system, constructing the corresponding simulation system. As shown in FIG. 1, the simplified container logistics supply chain system is shown,
an actual container logistics supply chain system containing the multitude of container ships, a container port and a container freight station, the multitude of container ships, the container port and the container freight station having a close interrelationship, they working together to achieve the smooth transportation and transshipment of goods, describing the details as below:
an upstream customer submitting the transportation order to the logistics service provider, according to the order requirements, the carrier transcontainer porting the shipper's goods to the corresponding container port by a container ship, the container port equipping with the multitude of cranes, the multitude of stackers and other equipment, after the container ship arriving at the container port, the container ship loading and unloading the multitude of goods in the container port; these loading and unloading operations requiring coordinated and precise time management to minimize cargo detention time, container handling pre-processing work is at this stage, at the same time, obtaining an actual arrival rate of the container, a waiting time of the container at the anchorage, a delay time of berth allocation, and a container operation time;
the container freight station is responsible for unloading the goods from the container ship, and in the freight station for temporary storage, distribution and reloading and other specific operations; in the loading and unloading process existing a certain delay, it is regarded as an inherent feature of the system, deriving the difference between the container processing capacity and the container processing completion rate level through data processing; finally, according to the shipper's requirements, distributing the multitude of goods in the multitude of containers to the end user or other destinations; simulating based on the above physical system;
As shown in FIG. 2, the main process of the resilience-enhancement control method of the container logistics supply chain based on adaptive fuzzy double feedback is shown. The container actual arrival rate CARATE, the container waiting time T_{WAIT}, the berth allocation delay time Tₚ₁, and the container operation time T_{P} being obtained from the container port master data management system as the input parameters of the container logistics supply chain simulation model; in the control link, the control method is used to obtain the output of the container logistics supply chain control model as the optimized adjustment time parameters T_{UCHR} and T_{FCPR}, so as to realize the real-time update of the system parameters T_{UCHR} and T_{FCPR}; the final simulation goal is to make the output unfinished container workload UCHR waveform less being affected and converging to 0 faster, enhancing the resilience of the container logistics supply chain system.

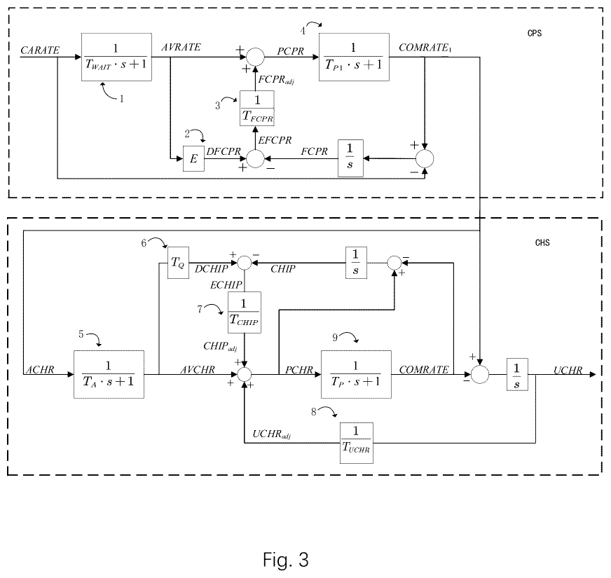

As shown in FIG. 3, the container logistics supply chain simulation system includes: the first one of the container pretreatment subsystem (CPS): container arrival preprocessing unit, expected preprocessing time unit, first adder, second adder, allocation delay strategy unit, and third adder; the second one of the container handling subsystem (CHS): container operation demand prediction unit, expected delay time unit, first adder, first adjustment time unit, second adjustment time unit, second adder, container operation delay strategy unit, third adder, and fourth adder. Among them, the input end of the container arrival preprocessing unit in the first subsystem of container pretreatment subsystem (CPS) inputs the actual arrival rate of the container at the container port CARATE, and the output end of the container arrival preprocessing unit is connected to the input end of the expected preprocessing time unit and the input end of the second adder, respectively. The output end of the expected preprocessing time unit is connected to the input end of the first adder. The input end of the first adder is also connected to the output end of the integration unit, and the output end of the first adder is connected to the input end of the adjustment time unit. Connect the output end of the adjustment time unit to the input end of the second adder. The output end of the second adder is connected to the input end of the allocation delay strategy unit. The output end of the allocation delay strategy unit is connected to the input end of the third adder, the input end of the container handling subsystem (CHS) container operation demand prediction unit, and the input end of the fourth adder, respectively. The input end of the third adder also inputs the actual container arrival rate CARATE, and the output end of the third adder is connected to the input end of the integration unit.

The output end of the container operation demand prediction unit in the second subsystem of container handling subsystem (CHS) is connected to the input end of the expected delay time unit and the input end of the second adder, respectively. The output end of the expected delay time unit is connected to the input end of the first adder. The input end of the first adder is also connected to the output end of the first integrating unit, and the output end of the first adder is connected to the input end of the first adjusting time unit. The output end of the first adjustment time unit is connected to the input end of the second adder. The input end of the second adder is also connected to the output end of the second adjustment time unit. The output end of the second adder is connected to the input end of the container operation delay strategy unit and the input end of the third adder, respectively. The output container ports of the container operation delay strategy unit being connected to the input container ports of the third adder and the input container ports of the fourth adder, respectively. The output end of the third adder is connected to the input end of the first integrating unit. The output end of the fourth adder is connected to the input end of the second integrating unit. The output end of the second integration unit is connected to the input end of the second adjustment time unit, outputting the UCHR of unfinished container operations at the container port.

the simulation method comprising:
Step 1, establishing a container logistics supply chain simulation system, containing two subsystems: container preprocessing subsystem CPS and container handling subsystem CHS, CPS and CHS appearing below refer to the simulation subsystem. the first one of the container pretreatment subsystem CPS comprising:
a container arrival pretreatment unit 1, an expected pretreatment time unit 2, an adjustment time unit 3 and an allocation delay strategy unit 4;
the second one of the container handling subsystem CHS comprising:
a container handling requirement forecasting unit 5, a desired delay time unit 6, a first adjustment time unit 7, a second adjustment time unit 8 and a container handling delay strategy unit 9;
a detailed description of each module is described below:
the container arrival preprocessing unit 1 setting the non-negative unit step function waveform as the actual arrival rate of the container CARATE, setting it as the system input, and performing the product operation through the built-in container arrival preprocessing function to output the average container arrival rate AVRATE;
the expected pretreatment time unit 2 setting the average container arrival rate AVRATE as input, and multiplying with the expected lead period E of the built-in pre-processing subsystem;
the expected container pretreatment requirement DFCPR subtracting the completed container pretreatment requirement FCPR obtained by the integral unit to obtain the container pretreatment demand difference EFCPR;
the adjustment time unit 3 setting the completed container preprocessing requirement difference EFCPR as input, and dividing the built-in adjustment time parameter TFCPR, and obtaining the operation result as the adjustment amount FCPRadj of FCPR;
the adjustment amount of FCPRadj and the average container arrival rate AVRATE being added to the output PCPR for the planned container pretreatment requirement;
the allocation delay strategy unit 4, setting the planned container preprocessing demand PCPR as input, and the built-in allocation delay strategy function

$$\frac{1}{{T}_{P 1} \cdot s + 1}$$

to do the product operation, the operation result is the allocation completion amount COMRATE1, COMRATE1 as the input of the container operation demand forecasting unit, and the container operation completion capacity COMRATE is subtracted, COMRATE1 minus the container operation completion capacity COMRATE; T_{P1} is the allocation delay time, and s is the complex frequency domain variable of the Laplace transform;
the container operation demand forecasting unit 5 multiplies the input container operation demand ACHR with the built-in container operation demand forecasting function

$$\frac{1}{{T}_{A} \cdot s + 1}$$

to output the average container operation demand AVCHR; T_{A} is the time constant of container operation demand forecasting, and s is the complex frequency domain variable of the Laplace transform;
the expected delay time unit 6 connecting with the container operation demand forecasting unit 5 to obtain the average container operation demand AVCHR as input, and the built-in expected delay time parameter T_{Q} is multiplied to output the expected container operation demand DCHIP;
subtracting the container operation requirement CHIP obtained by the first integral unit from the container operation requirement in processing DCHIP that is expected to be processed, and outputting the difference in container operation demand in processing ECHIP;
the first adjustment time unit 7, with ECHIP as input, and the built-in first adjustment time parameter TCHIP to do division operation, ECHIP dividing by TCHIP operation result is CHIPadj;
the second adjustment time unit 8 setting the unfinished container operation volume UCHR output by the model as input, and dividing the built-in second adjustment time TUCHR, and dividing UCHR by TUCHR to obtain the operation result of UCHRadj;
the adjustment amount of UCHRadj and the adjustment amount of CHIP CHIPadj and the AVCHR obtained by the container operation demand forecasting unit 5 being added to the sum of the three outputs for the container operation capacity PCHR;
the container operation delay strategy unit 9 setting the container operation capacity PCHR as the input, and the built-in container operation delay strategy function to do the product operation, and the output is the container operation completion capacity COMRATE; T_{P} is the actual delay time parameter; s is the complex frequency domain variable of the Laplace transform;
obtaining the container operation capacity PCHR and the container operation completion capacity RATE to do the subtraction operation, the operation result is output to the first integration unit, and the first integration unit outputting the container operation requirements in processing CHIP;
obtaining the container operation requirement ACHR, subtracting the container operation completion capacity COMRATE, and outputting the operation result to the second integration unit.
the connections between the units being described below:
the container arrival pretreatment unit 1 outputs the average container arrival rate AVRATE;
the expected pretreatment time unit 2 connecting with the container arrival pretreatment unit 1 for output, and the expected completion of the container pretreatment demand DFCPR is obtained;
the integral unit obtaining the completed container preprocessing requirements FCPR the adjustment time unit 3 receiving the output of the container arriving at the pretreatment unit 1 connecting with the expected pretreatment time unit 2, and outputting the adjustment amount FCPRadj of FCPR;
the delay strategy unit 4 is assigned to receive the output of the container arrival preprocessing unit 1 and the adjustment time unit 3, and obtaining the container operation completion amount COMRATE1, and using it as the input of the container handing subsystem;
the integration unit receiving the output of the allocation delay strategy unit 4 to obtain the container preprocessing requirement FCPR;
the container operation demand forecasting unit 5 outputting the average container operation demand AVCHR;
the expected delay time unit 6 and the container operation demand forecasting unit 5 being connecting for output to obtain the expected processing container operation demand DCHIP;
the first integral unit capturing the CHIP of the container operation requirements in process;
the first adjustment time unit 7 receiving the output of the container operation demand forecasting unit 5 and the expected delay time unit 6 connecting, and outputting the adjustment amount CHIPadj of CHIP;
the second adjustment time unit 8 receiving the unfinished container operation volume UCHR outputting by the model, and obtaining the adjustment amount UCHRadj of UCHR;
the container operation delay strategy unit 9 receiving the output of the first adjustment time unit 7 and the second adjustment time unit 8 and the container operation demand forecasting unit 5, and outputting the container operation completion capacity COMRATE.
the second integral unit receiving the unfinished container operation volume UCHR in the container port, and finally obtaining the UCHR output waveform of the container operation subsystem.
Step 2, based on the container logistics supply chain system comprising the container preprocessing subsystem and the container operation subsystem, describing the state space of the system, and obtaining the corresponding transfer function; Specific steps include:
Step 2.1, determining the transfer functions of COMRATE1 and the planned container pretreatment demand PCPR in the first subsystem CPS relative to the actual arrival rate of the container;
in the subsystem CPS, the variable integral of the difference between the container allocation completion rate COMRATE1 and the actual container arrival rate CARATE over time is taken as the pretreatment completion rate FCPR of the CPS in the container pretreatment stage;

FCPR(t)=∫(COMRATE₁(t)−CARATE(t))dt (1)
then, the planned container preprocessing requirement PCPR and the allocation delay strategy function

$$\frac{1}{{T}_{P 1} s + 1}$$

being multiplied to obtain the allocation completion rate COMRATE1 expressed by the indefinite integral, wherein decomposed into 1/S and 1/T_{P1} series when calculating

$$\frac{1}{{T}_{P 1} s + 1} ,$$

and adding a feedback loop;

$${COMRATE}_{1} ( t ) = \frac{1}{{T}_{p 1}} \int ( PCPR ( t ) - {COMRATE}_{1} ( t ) ) dt \qquad ( 2 )$$

the actual container arrival rate CARATE and the container operation delay strategy function

$$\frac{1}{{T}_{P} s + 1}$$

being multiplied to obtain the average container arrival rate AVRATE represented by the indefinite integral, wherein decomposed into 1/S and 1/T_{P} series when calculating, and adding a feedback loop

$$AVRATE ( t ) = \frac{1}{{T}_{WAIT}} \int ( CARATE ( t ) - AVRATE ( t ) ) d t \qquad ( 3 )$$

the container logistics supply chain simulation system selecting FCPR=x₁, ∫(PCPR(t)−COMRATE₁(t))dt=x₂, AVRATE·T_{WAIT}=x₃, where x₁ representing the completed container pretreatment requirement, x₂ representing the integral of the difference between the planned container pre-processing requirement and the allocated completion volume, and x₃ representing the average container actual arrival rate status, then:

$${\dot{x}}_{1} = \frac{1}{{T}_{p 1}} {x}_{2} - CARATE \qquad ( 4 )$$

$${\dot{x}}_{2} = - \frac{1}{{T}_{FCPR}} {x}_{1} - \frac{1}{{T}_{p 1}} {x}_{2} + \frac{1}{{T}_{WAIT}} ( 1 + E ) {x}_{3} \qquad ( 5 )$$

$${\dot{x}}_{3} = - \frac{1}{{T}_{WAIT}} {x}_{3} + CARATE \qquad ( 6 )$$

the preset container pretreatment requirement PCPR of the simulation is expressed as:

$$PCPR = - \frac{1}{{T}_{FCPR}} {x}_{1} + \frac{1}{{T}_{WAIT}} ( 1 + E ) {x}_{3} \qquad ( 7 )$$

the continuous closed-loop state space of CPS in the container pretreatment stage is expressed as:

$$\dot{x} = [ \begin{matrix}0 & \frac{1}{{T}_{p 1}} & 0 \\ - \frac{1}{{T}_{i}} & - \frac{1}{{T}_{p}} & \frac{1}{{T}_{WAIT}} ( 1 + E ) \\ 0 & 0 & - \frac{1}{{T}_{WAIT}}\end{matrix} ] x + [ \begin{matrix}- 1 \\ 0 \\ 1\end{matrix} ] CARATE \qquad ( 8 )$$

the transfer function of the allocation completion amount COMRATE1 and the planned container pretreatment demand PCPR relative to the actual arrival rate of the container CARATE in the container pretreatment subsystem CPS is:

$$\frac{{COMRATE}_{1}}{CARATE} = \frac{( {T}_{FCPR} + {T}_{WAIT} + E ) s + 1}{\begin{matrix}{T}_{FCPR} {T}_{p 1} {T}_{WAIT} [ 1 / {T}_{FCPR} {T}_{p 1} + 1 / {T}_{p 1} s + {s}^{2} ] \\ ( s + 1 / {T}_{WAIT} )\end{matrix}} \qquad ( 9 )$$

$$\frac{PCPR}{CARATE} = \frac{\begin{matrix}( {T}_{FCPR} {T}_{p 1} + {T}_{p 1} W + {T}_{p 1} {T}_{WAIT} ) {s}^{2} + \\ ( {T}_{FCPR} + E + {T}_{p 1} + {T}_{WAIT} ) s + 1\end{matrix}}{\begin{matrix}{T}_{FCPR} {T}_{p 1} {T}_{WAIT} [ 1 / {T}_{FCPR} {T}_{p 1} + 1 / {T}_{p 1} s + {s}^{2} ] \\ ( s + 1 / {T}_{WAIT} )\end{matrix}} \qquad ( 10 )$$

Step 2.2, determining the transfer function of the unfinished container operation volume UCHR and the container operation capacity PCHR relative to the container operation demand ACHR respectively in the second subsystem CHS;
in the subsystem CHS, the difference between the container operation requirement ACHR and the container operation completion capacity COMRATE is taken as the indefinite integral over time as the uncompleted container operation volume UCHR in the simulation;

UCHR(t)=∫(ACHR(t)−COMRATE(t))dt (11)
the difference between the container operation capacity PCHR and the container operation completion capacity CARRIER is taken as the variable integral over time as the container operation demand CHIP in processing;

CHIP(t)=∫(PCHR(t)−COMRATE(t))dt (12)
the container operation demand ACHR and the container operation demand forecasting function

$$\frac{1}{{T}_{A} \cdot s + 1}$$

being multiplied to obtain the average container operation demand AVCHR, wherein decomposed into 1/S and 1/T_{A} series when calculating

$$\frac{1}{{T}_{A} \cdot s + 1} ,$$

and the feedback loop is added from 1/T_{A},

$$AVCHR ( t ) = \frac{1}{{T}_{A}} \int ( ACHR ( t ) - AVCHR ( t ) ) dt \qquad ( 13 )$$

the container logistics supply chain simulation system selecting UCHR=x₄ CHIP=x₅, AVCHRTA=x₆, where x4 and x5 representing the outstanding container operation volume and the container operation demand in processing, respectively, and x6 representing the average container operation demand, then:

$${\dot{x}}_{4} = \frac{1}{{T}_{p}} {x}_{5} + ACHR \qquad ( 14 )$$

$${\dot{x}}_{5} = \frac{1}{{T}_{UCHR}} {x}_{4} - ( \frac{1}{{T}_{p}} + \frac{1}{{T}_{CHIP}} ) {x}_{5} + ( \frac{1}{{T}_{A}} + \frac{{T}_{Q}}{{T}_{CHIP} {T}_{A}} ) {x}_{6} \qquad ( 15 )$$

$${\dot{x}}_{6} = - \frac{1}{{T}_{A}} {x}_{6} + ACHR \qquad ( 16 )$$

the PCHR is:

$$PCHR = \frac{1}{{T}_{UCHR}} {x}_{4} - \frac{1}{{T}_{CHTP}} {x}_{5} + ( \frac{1}{{T}_{A}} + \frac{{T}_{Q}}{{T}_{CHIP} {T}_{A}} ) {x}_{6} \qquad ( 17 )$$

the transfer function of the unfinished container operation volume UCHR and the container operation capacity PCHR relative to the container operation requirement ACHR in the container operation subsystem CHS is:

$$\frac{UCHR}{ACHR} = \frac{( {T}_{P} + {T}_{CHIP} + {T}_{CHIP} {T}_{P} s ) ( 1 + {T}_{A} s ) - {T}_{Q} - {T}_{CHIP}}{\begin{matrix}{T}_{CHIP} {T}_{P} {T}_{A} [ 1 / {T}_{UCHR} {T}_{P} + \\ ( 1 / {T}_{CHIP} + 1 / {T}_{P} ) s + {s}^{2} ] ( s + 1 / {T}_{A} )\end{matrix}} \qquad ( 18 )$$

$$\frac{PCHR}{ACHR} = \frac{( 1 + {T}_{P} s ) [ {T}_{CHIP} + ( {T}_{CHIP} {T}_{A} - {T}_{U} {T}_{Q} - {T}_{UCHR} {T}_{CHIP} ) s ]}{\begin{matrix}{T}_{UCHR} {T}_{CHIP} {T}_{P} {T}_{A} [ 1 / {T}_{UCHR} {T}_{P} + \\ ( 1 / {T}_{CHIP} + 1 / {T}_{P} ) s + {s}^{2} ] ( s + 1 / {T}_{A} )\end{matrix}} \qquad ( 19 )$$

Step 2.3, determining transfer function between the unfinished container operation volume UCHR and the container operation capacity PCHR in the CHS relative to the actual arrival rate CARATE of the input container in the CPS, respectively;
the transfer function of the unfinished container operation volume UCHR and the container operation capacity PCHR relative to the actual arrival rate of the input container in the upper subsystem CARATE is as follows:

$$\frac{UCHR}{CARATE} = \frac{{COMRATE}_{1}}{CARATE} \cdot \frac{UCHR}{ACHR} \qquad ( 20 )$$

$$\frac{PCHR}{CARATE} = \frac{{COMRATE}_{1}}{CARATE} \cdot \frac{PCHR}{ACHR} \qquad ( 21 )$$

Step 2.4, after the transfer function is derived, the actual arrival rate CARATE of the container input in the first stage is represented as a non-negative unit step function waveform, and the final response state

$${lim}_{t \to ∞} uchr ( t )$$

is obtained according to the final value theorem

$${lim}_{t \to ∞} uchr ( t ) = {lim}_{s \to 0} sUCHR ( s ) .$$

the state space of the container logistics supply chain simulation system is described as:

$$\dot{x} = ( \begin{matrix}A & 0 \\ 0 & B\end{matrix} ) x + ( \begin{matrix}- 1 \\ 0 \\ 1 \\ 0 \\ 0 \\ 0\end{matrix} ) CARATE + ( \begin{matrix}0 \\ 0 \\ 0 \\ 1 \\ 0 \\ 1\end{matrix} ) ACHR \qquad ( 22 )$$

$$( \begin{matrix}PCPR \\ FCPR \\ {COMRATE}_{1} \\ PCHR \\ UCHR \\ CHIP\end{matrix} ) = Bx$$

$$Wherein ,$$

$$( 23 )$$

$$A = ( \begin{matrix}0 & \frac{1}{{T}_{p 1}} & 0 & & & \\ - \frac{1}{{T}_{i}} & - \frac{1}{{T}_{p}} & \frac{1}{{T}_{WAIT}} ( 1 + E ) & & & \\ 0 & 0 & - \frac{1}{{T}_{WAIT}} & & & \\ & & & 0 & \frac{1}{{T}_{p}} & 0 \\ & & & \frac{1}{{T}_{UCHR}} & - ( \frac{1}{{T}_{p}} + \frac{1}{{T}_{CHIP}} ) & ( \frac{1}{{T}_{A}} + \frac{{T}_{Q}}{{T}_{CHIP} {T}_{A}} ) \\ & & & 0 & 0 & - \frac{1}{{T}_{A}}\end{matrix} )$$

$$( 24 )$$

$$B = ( \begin{matrix}- \frac{1}{{T}_{FCPR}} & 0 & \frac{1}{{T}_{WAIT}} ( 1 + E ) & & & \\ 1 & 0 & 0 & & & \\ 0 & \frac{1}{{T}_{p 1}} & 0 & & & \\ & & & \frac{1}{{T}_{UCHR}} & - \frac{1}{{T}_{CHIP}} & ( \frac{1}{{T}_{A}} + \frac{{T}_{Q}}{{T}_{CHIP} {T}_{A}} ) \\ & & & 1 & 0 & 0 \\ & & & 0 & 1 & 0\end{matrix} )$$

when the actual container arrival rate CARATE input by the simulation subsystem CPS is a unit step signal, the final response of the model is obtained according to the final value theorem:

$${lim}_{s \to 0} s \cdot \frac{UCHR}{CARATE} = \frac{{T}_{UCHR} ( {T}_{P} - {T}_{Q} )}{{T}_{CHIP}} \qquad ( 25 )$$

$${lim}_{s \to 0} s \cdot \frac{PCHR}{CARATE} = 1 \qquad ( 26 )$$

$${lim}_{s \to 0} s \cdot \frac{{COMRATE}_{1}}{CARATE} = 1 \qquad ( 27 )$$

$${lim}_{s \to 0} s \cdot \frac{PCPR}{CARATE} = 1 \qquad ( 28 )$$

from equation (25), uchr(∞) depending on T_{UCHR} [symbol] T_{CHIP} [symbol] T_{P} and T_{Q}, when T_{P}=T_{Q}, uchr(∞)=0;
uchr(t) is the Laplace transform of UCHR, and s is the complex frequency domain variable of the Laplace transform;
Step 3, designing a two-dimensional indicator R to measure the resilience of the container logistics supply chain:

R=\sqrt{FL² RE²} (29)

FL=[∫₀^{∞}(PCHR(t))²dt/∫₀^{∞}(CARATE(t))²dt] (30)

RE=\sqrt{α[ITAE_{UCHR}]²+β[ITAE_{FCPR}]²} (31)

ITAE_{UCHR}=∫₀^{∞}t|E_{UCHR}|dt (32)

ITAE_{FCPR}=∫₀^{∞}t|E_{FCPR}|dt (33)
wherein, FL is used to characterize the fluctuation of the actual arrival rate of containers in the container pretreatment subsystem CPS when CARATE is input, and the fluctuation of the container operation capacity PCHR in the container operation subsystem CHS relative to the actual arrival rate of the container input container in the CPS subsystem, the smaller the fluctuation, the more accurate the response ability to the input of the CPS subsystem, and the higher the stability of the container logistics supply chain system. the calculation of FL comprehensively considering the system status of the CHS subsystem and the system input of the CPS subsystem, reflecting the bearing capacity of the container logistics supply chain system under the impact of adverse events, RE integrating the deviation value of the response of the two subsystems of the container logistics supply chain system as the deviation of the overall system; FL and RE reflecting the affordability and resilience of the container logistics supply chain system to a certain extent, but FL is biased towards the fluctuation degree within the container logistics supply chain system, and RE is biased towards the deviation of the output of the container logistics supply chain system, representing the degree of recovery under the influence of adverse events, FL and RE representing the bearing capacity and resilience of the supply chain system respectively, the smaller the internal fluctuation of the system, the stronger the bearing capacity, the smaller the degree of output deviation, and the stronger the resilience; ITAE_{UCHR} and ITAE_{FCPR} representing the accumulation of deviations of UCHR and FCPR with time, respectively; the smaller the values of ITAE_{UCHR} and ITAE_{FCPR}, the better the response and recovery ability of the system;
α and β being set as the proportional coefficients to make the orders of magnitude of ITAE_{UCHR} and ITAE_{FCPR} coordinate with FL; therefore, for the resilience index R, smaller R representing the better performance of the system; in formula (32-33), E_{UCHR} representing the deviation between the actual value of UCHR and the input actual container arrive rate CARATE, E_{FCPR} representing the deviation between the actual value of FCPR and the input actual container arrive rate CARATE; different from E_{FCPR}, E_{FCPR} is the difference of the finished container pretreatment requirement, representing the deviation between the desired value of FCPR DFCPR and FCPR; E_{UCHR}=uchr(t)−uchr(∞), E_{FCPR}=fcpr(t)−fcpr(∞); it can be obtained from Equation (25) that

$$uchr ( ∞ ) = {T}_{UCHR} ( {T}_{P} - {T}_{Q} ) / {T}_{CHIP} ;$$

$$fcpr ( ∞ ) = {lim}_{s \to 0} s \cdot FCPR / CARATE = 1.$$

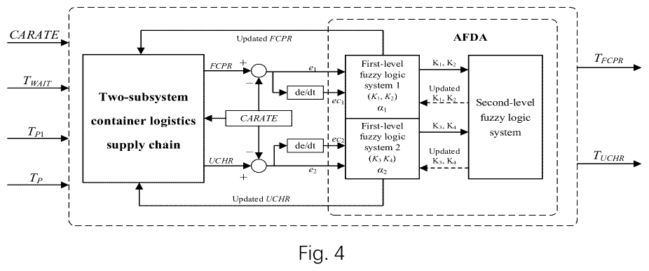

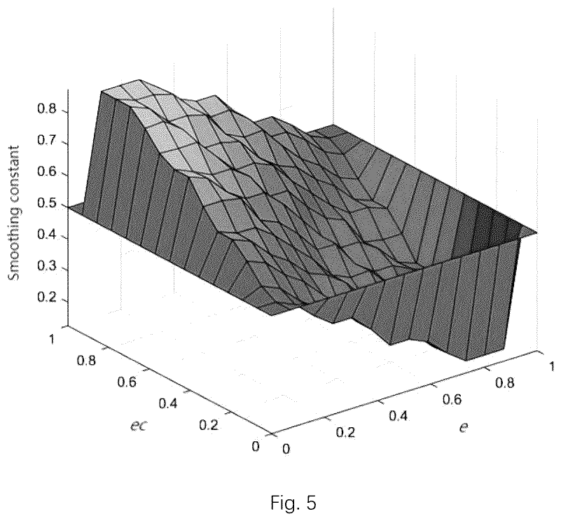

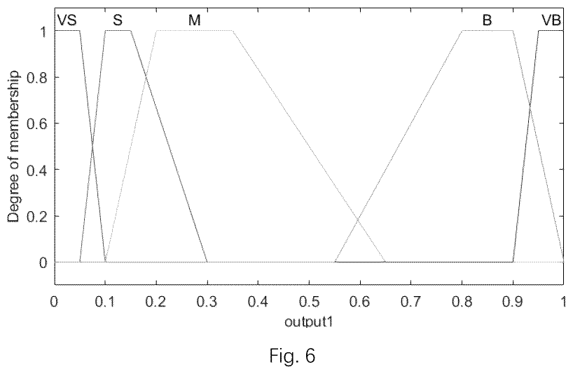

Step 4, based on the container preprocessing requirements FCPR and the container port's unfinished container workload UCHR, two feedback paths between the adaptive fuzzy control and the container logistics supply chain simulation system being constructed, and the adaptive fuzzy double feedback control structure is established; establishing an adaptive fuzzy double feedback control method comprising one-level fuzzy logic control and two-level adaptive fuzzy logic control, the specific steps comprising: FIG. 4 shows the block diagram of the resilience enhanced regulation strategy of container logistics supply chain simulation based on adaptive fuzzy dual feedback control, comprising:
Step 4.1, establishing a first first-level fuzzy logic system, setting the deviation e₁ between the actual container arrive rate CARATE and the finished container pretreatment requirement FCPR and the deviation change rate ec₁ as the inputs of the first first-level fuzzy logic system, further adjusting T_{FCPR} by controlling the change of smoothing coefficient α₁, feeding the updated FCPR back to the two-subsystem container logistics supply chain system;
Step 4.2, establishing a second first-level fuzzy logic system, setting the deviation e₂ between the actual container arrive rate CARATE and the unfinished container handling requirement UCHR and the deviation change rate ec₂ as the inputs of the second first-level fuzzy logic system, further adjusting T_{UCHR} by controlling the change of smoothing coefficient α₂, and feeding the updated UCHR back to the two-subsystem container logistics supply chain system;
Step 4.3, establishing a second-level adaptive fuzzy logic system; K₁ [symbol] K₂ and K₃ [symbol] K₄ being quantification factors of fuzzy inference inputs of the first second-level fuzzy logic system and the second second-level fuzzy logic system respectively, wherein the error quantification factor and error change rate quantification factor of the first fuzzy logic system being K₁, K₂ respectively, and the error quantification factor and error change rate quantification factor of the second fuzzy logic system being K₃ and K₄, respectively; adjusting the quantification factors online through the second-level adaptive fuzzy logic system; when the deviation is large, the main adaptive task is to eliminate the deviation, while when the deviation is small, the supply chain system is close to the steady state and the main adaptive task is to quickly adapt to changes of the external environment;
Step 4.4, designing the control rules of the first-level fuzzy logic system; for the first first-level fuzzy logic system and the second first-level fuzzy logic system, extracting the deviation e₁ and the deviation change rate e₁ between the actual container arrive rate CARATE and the finished container pretreatment requirement FCPR at the kth moment of the two-subsystem container logistics supply chain system, as well as the deviation e₂ and the deviation change rate ec₂ between the actual container arrive rate CARATE at the kth moment and the container port unfinished container handling requirement UCHR, setting e₁ [symbol] ec₁ and e₂ [symbol] ec₂ as the inputs of the first first-level fuzzy logic system and the second first-level fuzzy logic system respectively; defining the fuzzy subsets of the first-level fuzzy logic system as {VS(very small), S(small), RS(relatively small), M(medium), RB(relatively big), B(big), VB(very big)}, and the fuzzy domain as {0, 1}; the membership function of input and output adopting uniformly distributed trigonometric function. The corresponding membership function settings being shown in FIG. 6, according to the input and output requirements, the first-level fuzzy control rules being set as follows:

| | e | | | | | | |
|---|---|---|---|---|---|---|---|
| ec | VS | S | RS | M | RB | B | VB |
| VS | M | RS | RS | S | S | VS | VS |
| S | RB | M | RS | RS | S | S | VS |
| RS | RB | RB | M | RS | RS | S | S |
| M | B | RB | RB | M | RS | RS | S |
| RB | B | B | RB | RB | M | RS | RS |
| B | VB | B | B | RB | RB | M | RS |
| VB | VB | VB | B | B | RB | RB | M |

wherein e is the deviation and ec is the deviation change rate. From FIG. 5, it can be obtained that when the deviation e takes a value between 0 and 1, the smoothing coefficient α₁ and α₂ have the same trend as the deviation rate change rate ec. When the deviation change rate ec₁ and ec₂ being relatively large, increasing the smoothing coefficient α₂ to alleviate the rapid change of the supply chain system under the influence of adverse events, while when the deviation e₁ and e₂ being large, reducing the smoothing coefficient α₁ [symbol] α₂ to make the deviation e₁ and e₂ return to a more ideal state;
Step 5, designing the control rules of the second-level adaptive fuzzy logic system; setting quantization factors K₁, K₂, K₃ and K₄ as control objects; based on the update of smoothing coefficients, further updating the control effect of quantization factors on first-level fuzzy logic system, that is, when the input deviations e₁ and e₂ of two first-level fuzzy logic systems being large, the main task of adaptive is to increase the error quantization factors K₁ and K₃ to eliminate the deviation, and when the input deviation is small and the input deviation change rate ec₁ and ec₂ being large, the supply chain system is close to the steady state, making the main adaptive task is to increase the error change rate quantization factors K₂ and K₄ to make the system stable as soon as possible, so as to achieve the purpose of adaptive adjustment by using quantization factors;
setting the membership function corresponding to the input of the second-level adaptive fuzzy logic system as uniformly distributed trigonometric functions; setting the fuzzy subset as {NB(negative big), NM(negative middle), NS(negative small), Z(zero), PS(positive small), PM(positive middle), PB(positive big)}; defining the fuzzy subset of the output of adaptive fuzzy logic as {VS(very small), S(small), M(medium), B(big), VB(very big)}, the basic domain is {0, 1}; setting the second-level adaptive fuzzy control rules as:

| | e | | | | | | |
|---|---|---|---|---|---|---|---|
| ec | NB | NM | NS | Z | PS | PM | PB |
| NB | B | B | M | VS | S | M | B |
| NM | B | B | M | S | S | B | B |
| NS | VB | B | M | M | M | B | VB |
| Z | VB | B | B | M | B | B | VB |
| PS | VB | B | M | M | M | B | VB |
| PM | B | B | M | S | M | B | B |
| PB | B | M | S | VS | S | M | B |

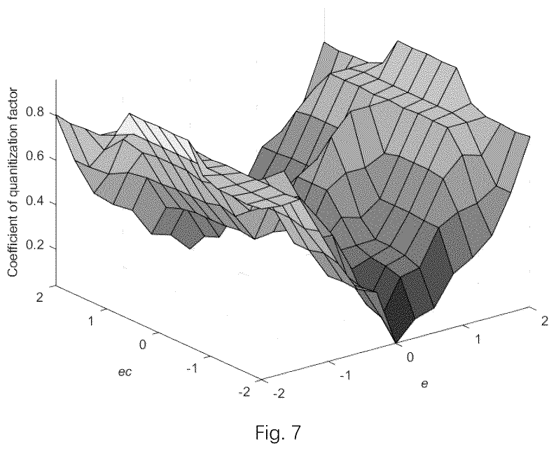

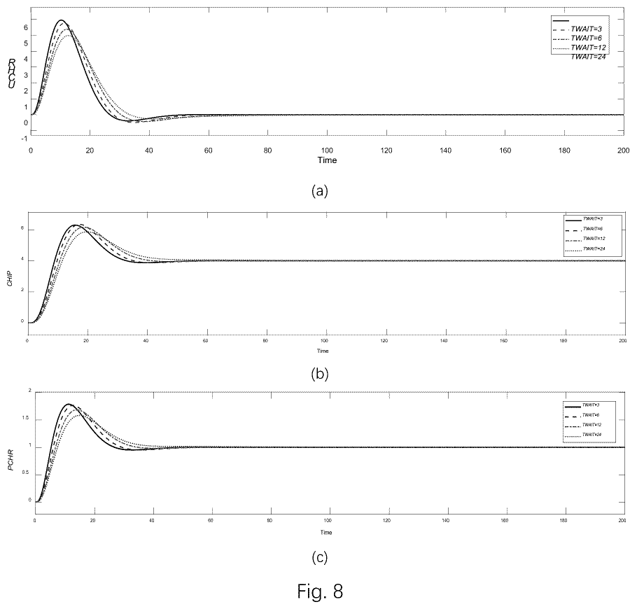

The input-output relationship corresponding to the two-level adaptive fuzzy control rule is shown in FIG. 7. As can be seen from FIG. 7, the fuzzy logic surface at this time shows obvious symmetry. When both the deviation e and the deviation change rate ec being close to zero (Z), the quantization factors K₁, K₂, K₃ and K₄ of the two inputs of the control fuzzy system having the same proportion; when the deviation e is close to 0 value and the deviation change rate ec tending to be large or small, the proportion of adjusting e is the smallest and that of ec is the largest; when the deviation rate ec is close to 0 value and the deviation e is large or small, adjusting the proportion of e to the maximum to achieve the purpose of adaptive adjustment.
Step 5, using the container logistics supply chain system resilience measurement method provided in Step 3 and the adaptive fuzzy double feedback control method provided in Step 4, verifying the effectiveness of the simulation method under the influence of adverse events; the steps comprising
Step 5.1, setting the average waiting time T_{WAIT} as 3˜24 cycles, setting the rated value of T_{WAIT} as 6 cycles; setting the FCPR adjustment time constant T_{FCPR} as 2˜16 cycles, setting the rated value of T_{FCPR} as 4 cycles; setting the average container port handling time T_{P} as 2˜6 cycles, setting the rated value of T_{P} as 4 cycles; setting the desired pretreatment period E as 1; setting the container handling forecasting requirement time constant T_{A}=6, T_{Q}=T_{P}=4; setting the allocation delay time T_{P1} as 0.5˜2 cycles, setting the rated value of T_{P1} as 1 cycle; simulating the influence of time constants T_{WAIT} and T_{FCPR} in the container pretreatment system on the response UCHR, CHIP and PCHR and resilience of the two-subsystem container logistics supply chain system, and analyzing of two-dimensional mechanism of resilience R;
Unit step signal is a commonly used test signal in control theory, suitable for studying various performance of dynamic systems. The present invention uses a unit step signal as the input for the two-subsystem container logistics supply chain under the influence of adverse events, and simulates and analyzes the impact of time constants T_{WAIT} and T_{FCPR} in the container preprocessing subsystem under the influence of adverse events on the response performance and resilience performance of the two-subsystem container logistics supply chain UCHR [symbol] CHIP and PCHR, as shown in FIGS. 8 to 11.
Step 5.2, setting UCHR and R as the response performance and resilience performance of the two-subsystem container logistics supply chain system, and T_{WAIT} as the main variable of the supply chain system; simulating and verifying the effectiveness of the resilience-enhancement control method of the container logistics supply chain based on adaptive fuzzy double feedback in increasing UCHR stability and shortening UCHR stability time, and the action mechanism of affordability and recovery ability on resilience under the resilience-enhancement control method of container logistics supply chain based on adaptive fuzzy double feedback is obtained; T_{A}, T_{P}, T_{Q}, E, T_{P1}, T_{WAIT}, T_{FCPR}, T_{CHIP}, T_{UCHR} being all being positive numbers.

From FIG. 8, it can be seen that the increase in T_{WAIT} leads to an extension of peak time and adjustment time, but the oscillation between UCHR and PCHR is smaller, and the increase in T_{WAIT} slightly reduces the peak levels of UCHR and PCHR. This means that under the influence of adverse events, it is difficult for the container logistics supply chain system to maintain its original stability, and the response efficiency significantly decreases with the extension of T_{WAIT}. When T_{WAIT} is 3 days, 6 days, 12 days, and 24 days respectively, the time for the supply chain system to reach stability will be reduced by 16.38%, 29.10%, 54.77%, and 88.51%, respectively. When T_{WAIT} is small, the peak level of CHIP does not change significantly, that is, there is no significant deviation between container port productivity and the planned processing rate of the container port, and the certain balance is still maintained when container ships being congested but the delay period is not too long.

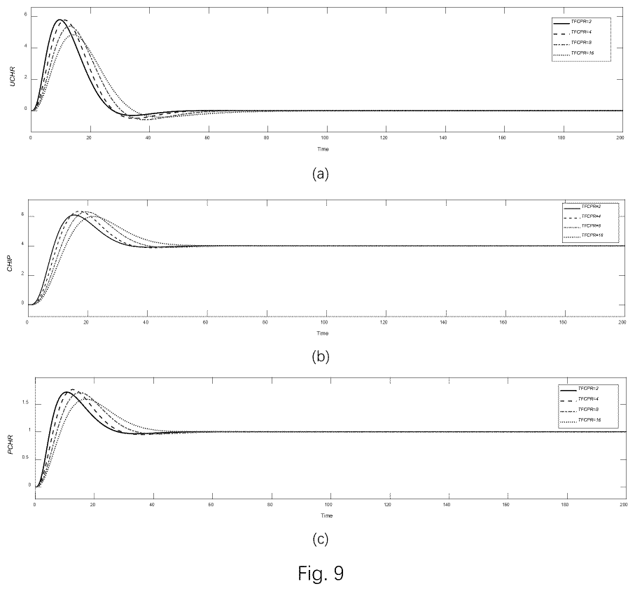

From FIG. 9, it can be seen that the increase in T_{FCPR} sacrifices longer adjustment time and peak time, and UCHR experiences fewer oscillations. At the smaller T_{FCPR} value, UCHR undergoes more oscillations, that is, the shorter the adjustment period of FCPR, the faster the system responds, the shorter the adjustment time of UCHR, and the shorter the time to reach steady-state. The peak levels of CHIP and PCHR show a slight increase and then a gradual decrease with the increase of T_{FCPR}.

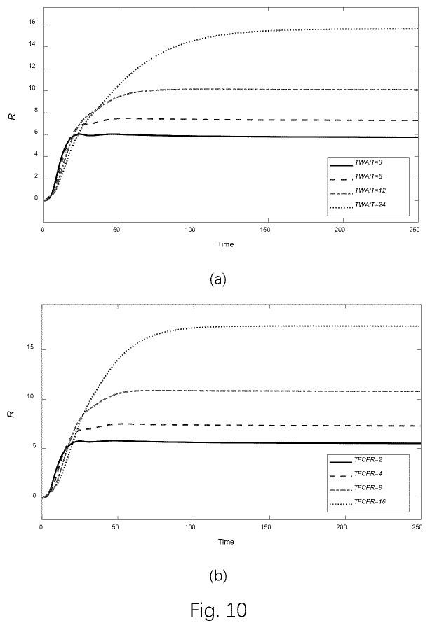

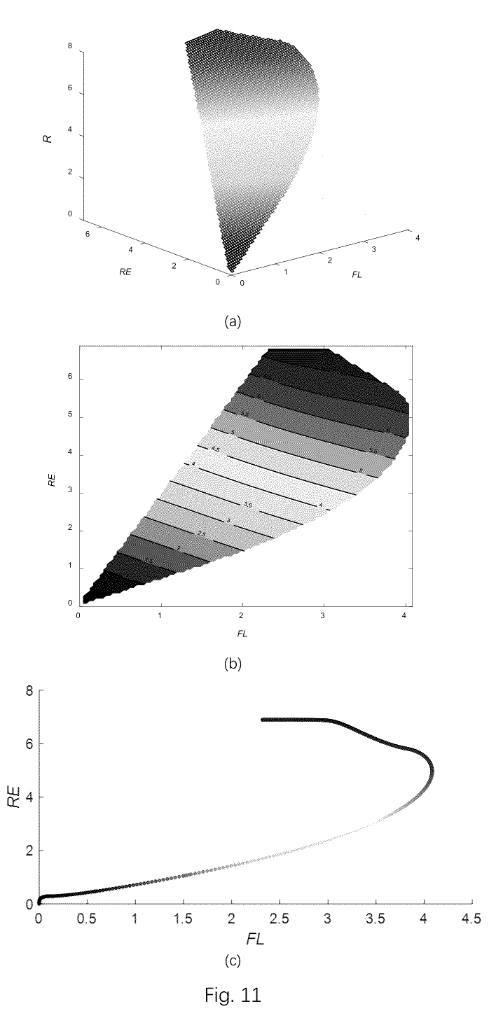

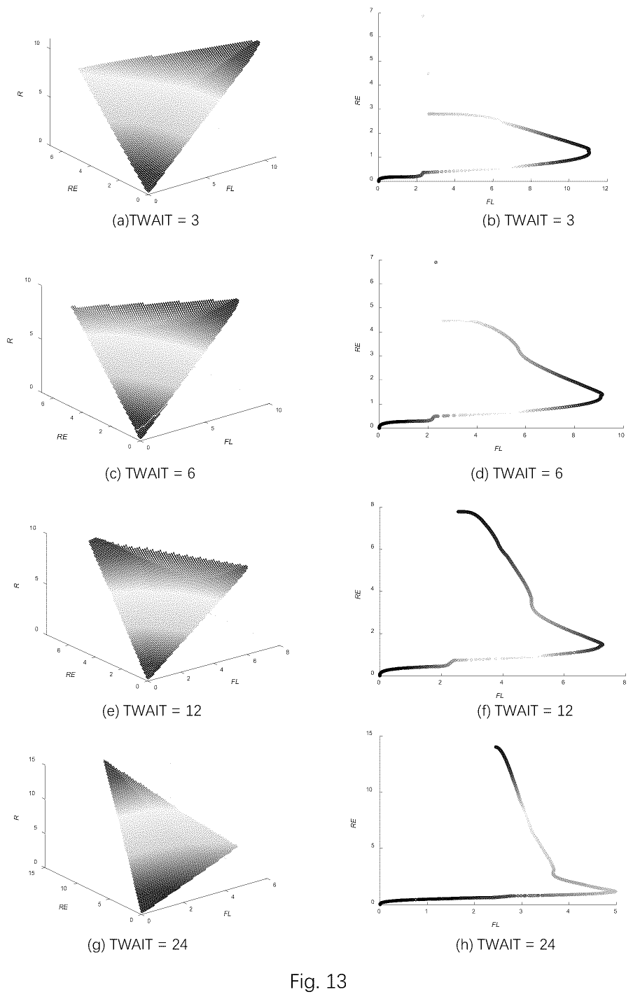

From FIG. 10, it can be seen that for smaller T_{WAIT} and T_{FCPR}, the response speed of the resilience index is faster, and the value of R is smaller. When TwAn=24 and T_{FCPR}=4, the resilience performance decreases to ¼ to ⅕ of the original. From FIG. 11, it can be seen that under the initial values of T_{WAIT}=6 and T_{FCPR}=4, both the bearing capacity FL and the recovery capacity RE have a gain effect on R, and the recovery capacity RE has a greater gain on the resilience index R than the bearing capacity FL, meaning that the recovery capacity has a greater weight comp being d to the bearing capacity. At this time, the resilience of the container logistics supply chain is mainly affected by the recovery capacity.
Step 4.2, In the two-subsystem container logistics supply chain, UCHR and R being the main control objects. Under the influence of adverse events, an adaptive fuzzy dual feedback control rules being adopted and combined with the actual experience of supply chain managers to control the smoothing coefficient, in order to obtain the optimized control parameters T_{UCHR} and T_{FCPR} of the container logistics supply chain system. The optimized T_{UCHR} and T_{FCPR} being applied to the actual container logistics supply chain operating system, in order to restore the container logistics supply chain as soon as possible. Set UCHR as the main response performance of the two-subsystem container logistics supply chain, OSC and tₛ to characterize the fluctuation degree and stability time of UCHR, R as the system resilience performance, and T_{WAIT} as the main variable of the supply chain. Comp being the response performance and resilience performance of the two-subsystem container logistics supply chain controlled by AFDA (adaptive fuzzy double feedback adjustment), PID (Proportional Integral Derivative), and TP (two pipelines) using the method of the present invention, As shown in FIG. 13, for the convenience of observation, the is value has been reduced by one order of magnitude.

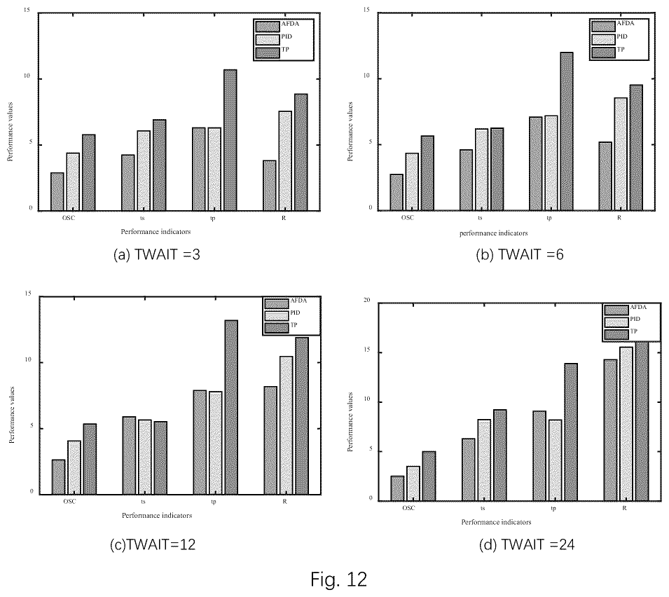

As shown in FIG. 12, the optimization effect of the AFDA method of the present invention on the supply chain system is obvious. The oscillation level of the supply chain system is significantly reduced, the response is faster, and the stability time is shorter. When T_{WAIT} is 3 days, 6 days, 12 days, and 24 days, the AFDA method of the present invention can shorten the stability time of the supply chain system by about 5 days, 7 days, 11 days, and 14 days, respectively. With the increase of T_{WAIT}, R shows an increasing trend. However, after being regulated by the method of the present invention, under different T_{WAIT} values, the resilience performance R of the supply chain system increases by 33.78%, 28.83%, 18.81%, and 8.49%, respectively.

Further decompose the R of the two-level container logistics supply chain system under the method of the present invention to explore the inherent two-dimensional mechanism of R under changes in the control parameter T_{WAIT}, as shown in FIG. 13. As shown in FIG. 13, the decomposition of R exhibits a certain variation pattern. When the value of T_{WAIT} is small, R is significantly more affected by the ability to withstand FL than by the ability to recover RE. As T_{WAIT} gradually increases, this trend begins to change. When the value of T_{WAIT} is large, the change in R is significantly dependent on the change in recovery ability RE, while the change in bearing capacity FL is no longer significant.

Although the content of the present invention has been described in detail through the above preferred embodiments, it should be recognized that the above description should not be considered a limitation of the present invention. After reading the above content, it will be apparent to technical personnel in this field that there being various modifications and substitutions to the present invention. Therefore, the accompanying claims limiting the scope of protection of the present invention;

1. A resilience enhanced simulation method for a container logistics supply chain system based on adaptive fuzzy double feedback, wherein the container logistics supply chain system comprising a multitude of container ships, a container port and a container freight station; the multitude of container ships, the container port and the container freight station coordinating for a smooth transportation and a transshipment of a goods:
the container ships arriving at the container port, the container port obtaining an actual arrival rate of the container, a waiting time of the container at an anchorage, a delay time of berth allocation, and a container operation time; the container freight station unloading the goods from the container ship, finally, according to a shipper's requirements, distributing a multitude of the goods in a multitude of containers to an end user or other destinations;
the resilience enhanced simulation method for the container logistics supply chain system based on adaptive fuzzy double feedback comprises the following steps:
step 1, establishing a container logistics supply chain simulation system, comprising two subsystems: a container preprocessing subsystem CPS and a container handling sub system CHS,
the container pretreatment subsystem CPS comprising:
a container arrival pretreatment unit (1), an expected pretreatment time unit (2), an adjustment time unit (3) and an allocation delay strategy unit (4);
the container handling subsystem CHS comprising:
a container handling requirement forecasting unit (5), a desired delay time unit (6), a first adjustment time unit (7), a second adjustment time unit (8) and a container handling delay strategy unit (9);
the container arrival preprocessing unit (1) setting a non-negative unit step function waveform as an actual arrival rate of the container CARATE, setting it as a system input, and performing a product operation through a built-in container arrival preprocessing function to output an average container arrival rate AVRATE;
an expected pretreatment time unit (2) setting the average container arrival rate AVRATE as input, and multiplying with an expected lead period E of a built-in pre-processing subsystem;
an expected container pretreatment requirement DFCPR subtracting a completed container pretreatment requirement FCPR from an integral unit to obtain a container pretreatment demand difference E_{FCPR};
the adjustment time unit (3) setting a completed container preprocessing requirement difference E_{FCPR} as input, and dividing a built-in adjustment time parameter T_{FCPR}, and obtaining an operation result as an adjustment amount FCPRadj of FCPR;
an adjustment amount of FCPRadj and the average container arrival rate AVRATE adding to an output PCPR for a planned container pretreatment requirement;
the allocation delay strategy unit (4), setting a planned container preprocessing demand PCPR as input, and a built-in allocation delay strategy function
$$\frac{1}{{T}_{P 1} \cdot s + 1}$$
to do a product operation, the operation result being an allocation completion amount COMRATE1, COMRATE1 as an input of the container operation demand forecasting unit, subtracting a container operation completion capacity COMRATE, T_{P1} being an allocation delay time, and s being a complex frequency domain variable of a Laplace transform; an allocation completion rate COMRATE₁ subtracting an actual container arrive rate CARATE, outputting a calculation result to the integral unit; the integral unit outputting a finished container pretreatment requirement FCPR;
the container operation demand forecasting unit (5) multiplying an input container operation demand ACHR with a built-in container operation demand forecasting function
$$\frac{1}{{T}_{A} \cdot s + 1}$$
to output an average container operation demand AVCHR; T_{A} being a time constant of container operation demand forecasting, and s being a complex frequency domain variable of the Laplace transform;
the expected delay time unit (6) connecting with the container operation demand forecasting unit (5) to obtain the average container operation demand AVCHR as input, and multiplying a built-in expected delay time parameter T_{Q} to output an expected container operation demand DCHIP;
subtracting a container operation requirement CHIP obtained by a first integral unit from a container operation requirement in processing DCHIP, and outputting a difference in container operation demand in processing ECHIP;
the first adjustment time unit (7), with ECHIP as input, and a built-in first adjustment time parameter TCHIP to do division operation, ECHIP dividing by TCHIP operation result being CHIPadj;
the second adjustment time unit (8) setting an unfinished container operation volume UCHR output by a model as input, and dividing a built-in second adjustment time TUCHR, and dividing UCHR by TUCHR to obtain an operation result of UCHRadj;
an adjustment amount of UCHRadj and an adjustment amount of CHIP CHIPadj and the AVCHR obtaining from the container operation demand forecasting unit (5) adding to a sum of three outputs for a container operation capacity PCHR;
the container operation delay strategy unit (9) setting the container operation capacity PCHR as the input, and a built-in container operation delay strategy function to do the product operation, and the output being the container operation completion capacity COMRATE; T_{P} being an actual delay time parameter; s being the complex frequency domain variable of the Laplace transform;
obtaining the container operation capacity PCHR and the container operation completion capacity RATE to do a subtraction operation, the operation result outputting to the first integration unit, and a first integration unit outputting the container operation requirements in processing CHIP;
obtaining the container operation requirements ACHR, subtracting the container operation completion capacity COMRATE, and outputting the operation result to the second integration unit;
the container arrival pretreatment unit (1) outputting the average container arrival rate AVRATE;
the expected pretreatment time unit (2) connecting with the container arrival pretreatment unit (1) for output, and obtaining an expected completion of the container pretreatment demand DFCPR;
the integral unit obtaining a completed container preprocessing requirements FCPR the adjustment time unit (3) receiving an output of the container arriving at the pretreatment unit (1) connecting with the expected pretreatment time unit (2), and outputting the adjustment amount FCPRadj of FCPR;
the delay strategy unit (4) being to receive the output of the container arrival preprocessing unit (1) and the adjustment time unit (3), and obtaining the container operation completion amount COMRATE1, and using it as the input of the container handing subsystem;
the integration unit receiving the output of the allocation delay strategy unit (4), obtaining the container preprocessing requirement FCPR;
the container operation demand forecasting unit (5) outputting the average container operation demand AVCHR;
connecting the expected delay time unit (6) and the container operation demand forecasting unit (5) for output, obtaining the expected processing container operation demand DCHIP;
the first integral unit capturing the CHIP of the container operation requirements in process;
the first adjustment time unit (7) receiving the output of the container operation demand forecasting unit (5) and the expected delay time unit (6) connecting, and outputting the adjustment amount CHIPadj of CHIP;
the second adjustment time unit (8) receiving the unfinished container operation volume UCHR outputting by the model, and obtaining the adjustment amount UCHRadj of UCHR;
the container operation delay strategy unit (9) receiving the output of the first adjustment time unit (7) and the second adjustment time unit (8) and the container operation demand forecasting unit (5), and outputting the container operation completion capacity COMRATE;
the second integral unit receiving the unfinished container operation volume UCHR in the container port, and finally obtaining the UCHR output waveform of the container operation sub system;
step 2, based on the container logistics supply chain system comprising the container preprocessing subsystem and the container operation subsystem, describing the state space of the system, and obtaining the corresponding transfer function;
step 2.1, determining the transfer functions of COMRATE1 and the planned container pretreatment demand PCPR in a first subsystem CPS relative to the actual arrival rate of the container;
in the subsystem CPS, setting the variable integral of the difference between the container allocation completion rate COMRATE1 and an actual container arrival rate CARATE over time as a pretreatment completion rate FCPR of the CPS in the container pretreatment subsystem;
FCPR(t)=∫(COMRATE₁(t)−CARATE(t))dt (1)
then, multiplying a planned container preprocessing requirement PCPR and the allocation delay strategy function
$$\frac{1}{{T}_{P 1} s + 1} ,$$
obtaining the allocation completion rate COMRATE1 expressed by the indefinite integral, wherein decomposing into 1/S and 1/T_{P}1 series when calculating
$$\frac{1}{{T}_{P 1} s + 1} ,$$
and adding a feedback loop;
$${COMRATE}_{1} ( t ) = \frac{1}{{T}_{p 1}} \int ( PCPR ( t ) - {COMRATE}_{1} ( t ) ) dt \qquad ( 2 )$$
multiplying the actual container arrival rate CARATE and the container operation delay strategy function
$$\frac{1}{{T}_{P} s + 1} ,$$
obtaining the average container arrival rate AVRATE represented by an indefinite integral, wherein decomposing into 1/S and 1/T_{P} series when calculating, and adding a feedback loop
$$AVRATE ( t ) = \frac{1}{{T}_{WAIT}} \int ( CARATE ( t ) - AVRATE ( t ) ) dt \qquad ( 3 )$$
the container logistics supply chain simulation system selecting FCPR=x₁, ∫(PCPR(t)−COMRATE₁(t)dt=x₂, AVRATE·T_{WAIT}=x₃, where x₁ representing the completed container pretreatment requirement, x₂ representing the integral of the difference between the planned container pre-processing requirement and the allocated completion volume, and x₃ representing the average container actual arrival rate status, then:
$${\dot{x}}_{1} = \frac{1}{{T}_{p 1}} {x}_{2} - CARATE \qquad ( 4 )$$
$${\dot{x}}_{2} = - \frac{1}{{T}_{FCPR}} {x}_{1} - \frac{1}{{T}_{p 1}} {x}_{2} + \frac{1}{{T}_{WAIT}} ( 1 + E ) {x}_{3} \qquad ( 5 )$$
$${\dot{x}}_{3} = \frac{1}{{T}_{WAIT}} {x}_{3} + CARATE \qquad ( 6 )$$
describing a preset container pretreatment requirement PCPR of the simulation as:
$$PCPR = - \frac{1}{{T}_{FCPR}} + \frac{1}{{T}_{WAIT}} {x}_{1} ( 1 + E ) {x}_{3} \qquad ( 7 )$$
describing the continuous closed-loop state space of CPS in the container pretreatment stage as:
$$\dot{x} = [ \begin{matrix}0 & \frac{1}{{T}_{p 1}} & 0 \\ - \frac{1}{{T}_{i}} & - \frac{1}{{T}_{p}} & \frac{1}{{T}_{WAIT}} ( 1 + E ) \\ 0 & 0 & - \frac{1}{{T}_{WAIT}}\end{matrix} ] x + [ \begin{matrix}- 1 \\ 0 \\ 1\end{matrix} ] CARATE \qquad ( 8 )$$
describing the transfer function of the allocation completion amount COMRATE1 and the planned container pretreatment demand PCPR relative to the actual arrival rate of the container CARATE in the container pretreatment subsystem CPS as:
$$\frac{{COMRATE}_{1}}{CARATE} = \frac{( {T}_{FCPR} + {T}_{WAIT} + E ) s + 1}{{T}_{FCPR} {T}_{p 1} {T}_{WAIT} [ 1 / {T}_{FCPR} {T}_{p 1} + 1 / {T}_{p 1} s + {s}^{2} ] ( s + 1 / {T}_{WAIT} )} \qquad ( 9 )$$
$$\frac{PCPR}{CARATE} = \frac{\begin{matrix}( {T}_{FCPR} {T}_{p 1} + {T}_{p 1} W + {T}_{p 1} {T}_{WAIT} ) {s}^{2} + \\ ( {T}_{FCPR} + E + {T}_{p 1} + {T}_{WAIT} ) s + 1\end{matrix}}{{T}_{FCPR} {T}_{p 1} {T}_{WAIT} [ 1 / {T}_{FCPR} {T}_{p 1} + 1 / {T}_{p 1} s + {s}^{2} ] ( s + 1 / {T}_{WAIT} )} \qquad ( 10 )$$
step 2.2, determining a transfer function of the unfinished container operation volume UCHR and the container operation capacity PCHR relative to a container operation demand ACHR respectively in a second subsystem CHS;
in the subsystem CHS, setting the difference between the container operation requirement ACHR and the container operation completion capacity COMRATE as the indefinite integral over time as the uncompleted container operation volume UCHR in the simulation;
UCHR(t)=∫(ACHR(t)−COMRATE(t))dt (11)
setting the difference between the container operation capacity PCHR and the container operation completion capacity CARRIER as the variable integral over time as the container operation demand CHIP in processing;
CHIP(t)=∫(PCHR(t)−COMRATE(t))dt (12)
multiplying the container operation demand ACHR and a container operation demand forecasting function
$$\frac{1}{{T}_{A} \cdot s + 1}$$
to obtain the average container operation demand AVCHR, wherein decomposing into 1/S and 1/T_{A} series when calculating
$$\frac{1}{{T}_{A} \cdot s + 1} ,$$
and adding a feedback loop from 1/T_{A},
$$AVCHR ( t ) = \frac{1}{{T}_{A}} \int ( ACHR ( t ) - AVCHR ( t ) ) dt \qquad ( 13 )$$
the container logistics supply chain simulation system selecting UCHR=x₄, CHIP=x₅, AVCHR·TA=x₆, where x4 and x5 representing the outstanding container operation volume and the container operation demand in processing, respectively, and x6 representing the average container operation demand, then:
$${\dot{x}}_{4} = \frac{1}{{T}_{p}} {x}_{5} + ACHR \qquad ( 14 )$$
$${\dot{x}}_{5} = \frac{1}{{T}_{UCHR}} {x}_{4} - ( \frac{1}{{T}_{p}} + \frac{1}{{T}_{CHIP}} ) {x}_{5} + ( \frac{1}{{T}_{A}} + \frac{{T}_{Q}}{{T}_{CHIP} {T}_{A}} ) {x}_{6} \qquad ( 15 )$$
$${\dot{x}}_{6} = - \frac{1}{{T}_{A}} {x}_{6} + ACHR \qquad ( 16 )$$
the PCHR being:
$$PCHR = \frac{1}{{T}_{UCHR}} {x}_{4} - \frac{1}{{T}_{CHTP}} {x}_{5} + ( \frac{1}{{T}_{A}} + \frac{{T}_{Q}}{{T}_{CHIP} {T}_{A}} ) {x}_{6} \qquad ( 17 )$$
describing the transfer function of the unfinished container operation volume UCHR and the container operation capacity PCHR relative to the container operation requirement ACHR in the container operation subsystem CHS as:
$$\frac{UCHR}{ACHR} = \frac{( {T}_{P} + {T}_{CHIP} + {T}_{CHIP} {T}_{P} s ) ( 1 + {T}_{A} s ) - {T}_{Q} - {T}_{CHIP}}{{T}_{CHIP} {T}_{P} {T}_{A} [ 1 / {T}_{UCHR} {T}_{P} + ( 1 / {T}_{CHIP} + 1 / {T}_{P} ) s + {s}^{2} ] ( s + 1 / {T}_{A} )} \qquad ( 18 )$$
$$\frac{PCHR}{ACHR} = \frac{( 1 + {T}_{P} s ) [ {T}_{CHIP} + ( {T}_{CHIP} {T}_{A} - {T}_{U} {T}_{Q} - {T}_{UCHR} {T}_{CHIP} ) s ]}{\begin{matrix}{T}_{UCHR} {T}_{CHIP} {T}_{P} {T}_{A} [ 1 / {T}_{UCHR} {T}_{P} + \\ ( 1 / {T}_{CHIP} + 1 / {T}_{P} ) s + {s}^{2} ] ( s + 1 / {T}_{A} )\end{matrix}} \qquad ( 19 )$$
step 2.3, determining a transfer function between the unfinished container operation volume UCHR and the container operation capacity PCHR in the CHS relative to the actual arrival rate CARATE of the input container in the CPS, respectively;
describing the transfer function of the unfinished container operation volume UCHR and the container operation capacity PCHR relative to the actual arrival rate of the input container in an upper subsystem CARATE as follows:
$$\frac{UCHR}{CARATE} = \frac{{COMRATE}_{1}}{CARATE} \cdot \frac{UCHR}{ACHR} \qquad ( 20 )$$
$$\frac{PCHR}{CARATE} = \frac{{COMRATE}_{1}}{CARATE} \cdot \frac{PCHR}{ACHR} \qquad ( 21 )$$
step 2.4, after deriving a transfer function, an actual arrival rate CARATE of the container input in a first stage representing as the non-negative unit step function waveform, and obtaining the final response state
$${}_{t \to ∞} uchr ( t )$$
according to a final value theorem
$${}_{t \to ∞} uchr ( t ) = {}_{s \to 0} sUCHR ( s ) ;$$
describing a state space of the container logistics supply chain simulation system as:
$$\dot{x} = ( \begin{matrix}A & 0 \\ 0 & B\end{matrix} ) x + ( \begin{matrix}- 1 \\ 0 \\ 1 \\ 0 \\ 0 \\ 0\end{matrix} ) CARATE + ( \begin{matrix}0 \\ 0 \\ 0 \\ 1 \\ 0 \\ 1\end{matrix} ) ACHR ( \begin{matrix}PCHR \\ FCHR \\ {COMRATE}_{1} \\ PCHR \\ UCHR \\ CHIP\end{matrix} ) = {B}_{x} \qquad ( 22 )$$
$$wherein ,$$
$$\begin{matrix}A = ( \begin{matrix}0 & \frac{1}{{T}_{p 1}} & 0 & 0 & \frac{1}{{T}_{p}} & 0 \\ - \frac{1}{{T}_{i}} & - \frac{1}{{T}_{p}} & \frac{1}{{T}_{WAIT}} ( 1 + E ) & \frac{1}{{T}_{UCHR}} & - ( \frac{1}{{T}_{p}} + \frac{1}{{T}_{CHIP}} ) & ( \frac{1}{{T}_{A}} + \frac{{T}_{Q}}{{T}_{CHIP} {T}_{A}} ) \\ 0 & 0 & - \frac{1}{{T}_{WAIT}} & 0 & 0 & - \frac{1}{{T}_{A}}\end{matrix} ) & ( 23 )\end{matrix}$$
$$B = ( \begin{matrix}- \frac{1}{{T}_{FCPR}} & 0 & \frac{1}{{T}_{WAIT}} ( 1 + E ) & \frac{1}{{T}_{UCHR}} & - \frac{1}{{T}_{CHIP}} & ( \frac{1}{{T}_{A}} + \frac{{T}_{Q}}{{T}_{CHIP} {T}_{A}} ) \\ 1 & 0 & 0 & 1 & 0 & 0 \\ 0 & \frac{1}{{T}_{p 1}} & 0 & 0 & 1 & 0\end{matrix} ) \qquad ( 24 )$$
when the actual container arrival rate CARATE input by a simulation subsystem CPS being a unit step signal, obtaining a final response of the model according to the final value theorem:
$${}_{s \to 0} s \cdot \frac{UCHR}{CARATE} = \frac{{T}_{UCHR} ( {T}_{P} - {T}_{Q} )}{{T}_{CHIP}} \qquad ( 25 )$$
$${}_{s \to 0} s \cdot \frac{PCHR}{CARATE} = 1 \qquad ( 26 )$$
$${}_{s \to 0} s \cdot \frac{{COMRATE}_{1}}{CARATE} = 1 \qquad ( 27 )$$
$${}_{s \to 0} s \cdot \frac{PCPR}{CARATE} = 1 \qquad ( 28 )$$
from equation (25), uchr(∞) depending on T_{UCHR} [symbol] T_{CHIP} [symbol] T_{P} and T_{Q}, when T_{P}=T_{Q}, uchr (∞)=0;
uchr(t) being the Laplace transform of UCHR, and s being the complex frequency domain variable of the Laplace transform;
step 3, designing a two-dimensional indicator R to measure the resilience of the container logistics supply chain:
R=\sqrt{FL² RE²} (29)
FL=[∫₀^{∞}(PCHR(t))²dt/∫₀^{∞}(CARATE(t))²dt] (30)
RE=\sqrt{α[ITAE_{UCHR}]²+β[ITAE_{FCPR}]²} (31)
ITAE_{UCHR}=∫₀^{∞}t|E_{UCHR}|dt (32)
ITAE_{FCPR}=∫₀^{∞}t|E_{FCPR}|dt (33)
wherein, using FL to characterize the fluctuation of the actual arrival rate of containers in the container pretreatment subsystem CPS when inputting CARATE, and a fluctuation of the container operation capacity PCHR in the container operation subsystem CHS relative to the actual arrival rate of the container input container in the CPS subsystem, the smaller the fluctuation, the more accurate the response ability to the input of the CPS subsystem, and the higher the stability of the container logistics supply chain system. the calculation of FL comprehensively considering the system status of the CHS subsystem and the system input of the CPS subsystem, reflecting the bearing capacity of the container logistics supply chain system under a impact of adverse events, RE integrating a deviation value of the response of the two subsystems of the container logistics supply chain system as a deviation of a overall system; FL and RE reflecting a affordability and resilience of the container logistics supply chain system to a certain extent, but FL biasing towards a fluctuation degree within the container logistics supply chain system, and RE biasing towards a deviation of the output of the container logistics supply chain system, representing a degree of recovery under the influence of adverse events, FL and RE representing a bearing capacity and resilience of the supply chain system respectively, the smaller the internal fluctuation of the system, the stronger the bearing capacity, the smaller the degree of output deviation, and the stronger the resilience;
ITAE_{UCHR} and ITAE_{FCPR} representing an accumulation of deviations of UCHR and FCPR with time, respectively; the smaller the values of ITAE_{UCHR} and ITAE_{FCPR}, the better the response and recovery ability of the system;
setting α and β as proportional coefficients to make orders of magnitude of ITAE_{UCHR} and ITAE_{FCPR} coordinate with FL; therefore, for a resilience index R, smaller R representing a better performance of the system; in formula (32-33), E_{UCHR} representing a deviation between the actual value of UCHR and an input actual container arrive rate CARATE, E_{FCPR} representing a deviation between an actual value of FCPR and an input actual container arrive rate CARATE; different from EFCPR, EFCPR being the difference of the finished container pretreatment requirement, representing a deviation between a desired value of FCPR DFCPR and FCPR;
wherein E_{UCHR}=uchr(t)−uchr(∞), E_{FCPR}=fcpr(t)−fcpr(∞); from Equation (25), obtaining
$$uchr ( ∞ ) = {T}_{UCHR} ( {T}_{P} - {T}_{Q} ) / {T}_{CHIP} ; fcpr ( ∞ ) = {}_{s \to 0} s \cdot FCPR / CARATE = 1 ;$$
step 4, based on a container preprocessing requirements FCPR and a container port's unfinished container workload UCHR, constructing two feedback paths between an adaptive fuzzy control and the container logistics supply chain simulation system, establishing an adaptive fuzzy double feedback control structure; establishing an adaptive fuzzy double feedback control method comprising one-level fuzzy logic control and two-level adaptive fuzzy logic control, the specific steps comprising:
step 4.1, establishing a first first-level fuzzy logic system, setting a deviation e₁ between the actual container arrive rate CARATE and the finished container pretreatment requirement FCPR and a deviation change rate ec₁ as the inputs of the fisrt first-level fuzzy logic system, further adjusting T_{FCPR} by controlling a change of smoothing coefficient α₁, feeding the updated FCPR back to a two-subsystem container logistics supply chain system;
step 4.2, establishing a second first-level fuzzy logic system, setting a deviation e₂ between the actual container arrive rate CARATE and the unfinished container handling requirement UCHR and a deviation change rate ec₂ as the inputs of the second first-level fuzzy logic system, further adjusting T_{UCHR} by controlling the change of smoothing coefficient α₂, and feeding the updated UCHR back to the two-subsystem container logistics supply chain system;
step 4.3, establishing a second-level adaptive fuzzy logic system; K₁ [symbol] K₂ and K₃ [symbol] K₄ being quantification factors of fuzzy inference inputs of a first second-level fuzzy logic system and a second second-level fuzzy logic system respectively, wherein the error quantification factor and error change rate quantification factor of the first fuzzy logic system being K₁, K₂ respectively, and the error quantification factor and error change rate quantification factor of the second fuzzy logic system being K₃ and K₄, respectively; adjusting the quantification factors online through a second-level adaptive fuzzy logic system; when the deviation being large, the main adaptive task being to eliminate the deviation, while when the deviation being small, the supply chain system being close to the steady state and the main adaptive task being to quickly adapt to changes of the external environment;
step 4.4, designing the control rules of the first-level fuzzy logic system; for the first first-level fuzzy logic system and the second first-level fuzzy logic system, extracting the deviation e₁ and the deviation change rate e₁ between the actual container arrive rate CARATE and the finished container pretreatment requirement FCPR at the kth moment of the two-subsystem container logistics supply chain system, as well as the deviation e₂ and the deviation change rate ec₂ between the actual container arrive rate CARATE at a kth moment and the container port unfinished container handling requirement UCHR, setting e₁ [symbol] ec₁ and e₂ [symbol] ec₂ as the inputs of the first first-level fuzzy logic system and the second first-level fuzzy logic system respectively; defining a fuzzy subsets of the first-level fuzzy logic system as {VS(very small), S(small), RS(relatively small), M(medium), RB(relatively big), B(big), VB(very big)}, and the fuzzy domain as {0, 1}; a membership function of input and output adopting uniformly distributed trigonometric function; according to the input and output requirements, the first-level fuzzy control rules being set as follows:

| | e | | | | | | |
|---|---|---|---|---|---|---|---|
| ec | VS | S | RS | M | RB | B | VB |
| VS | M | RS | RS | S | S | VS | VS |
| S | RB | M | RS | RS | S | S | VS |
| RS | RB | RB | M | RS | RS | S | S |
| M | B | RB | RB | M | RS | RS | S |
| RB | B | B | RB | RB | M | RS | RS |
| B | VB | B | B | RB | RB | M | RS |
| VB | VB | VB | B | B | RB | RB | M |

wherein e being a deviation and ec being a deviation change rate; when the deviation change rate ec₁ and ec₂ being relatively large, increasing the smoothing coefficient α₂ to alleviate the rapid change of the supply chain system under the influence of adverse events, while when the deviation e₁ and e₂ being large, reducing the smoothing coefficient α₁ [symbol] α₂ to make the deviation e₁ and e₂ return to a more ideal state;
step 5, designing a control rules of the second-level adaptive fuzzy logic system;
setting quantization factors K₁, K₂, K₃ and K₄ as control objects; based on an update of smoothing coefficients, further updating a control effect of quantization factors on first-level fuzzy logic system, that is, when the input deviations e₁ and e₂ of two first-level fuzzy logic systems being large, the main task of adaptive being to increase the error quantization factors K₁ and K₃ to eliminate the deviation, the input deviation being small and the input deviation change rate ec₁ and ec₂ being large, the supply chain system being close to the steady state, making the main adaptive task being to increase the error change rate quantization factors K₂ and K₄ to make the system stable as soon as possible, so as to achieve the purpose of adaptive adjustment by using quantization factors;
setting a membership function corresponding to the input of the second-level adaptive fuzzy logic system as uniformly distributed trigonometric functions; setting a fuzzy subset as {NB(negative big), NM(negative middle), NS(negative small), Z(zero), PS(positive small), PM(positive middle), PB(positive big)}; defining a fuzzy subset of the output of adaptive fuzzy logic as {VS(very small), S(small), M(medium), B(big), VB(very big)}, the basic domain being {0, 1}; setting the second-level adaptive fuzzy control rules as:

| | e | | | | | | |
|---|---|---|---|---|---|---|---|
| ec | NB | NM | NS | Z | PS | PM | PB |
| NB | B | B | M | VS | S | M | B |
| NM | B | B | M | S | S | B | B |
| NS | VB | B | M | M | M | B | VB |
| Z | VB | B | B | M | B | B | VB |
| PS | VB | B | M | M | M | B | VB |
| PM | B | B | M | S | M | B | B |
| PB | B | M | S | VS | S | M | B |

when both the deviation e and the deviation change rate ec being close to zero (Z), the quantization factors K₁, K₂, K₃ and K₄ of the two inputs of the control fuzzy system having the same proportion; when the deviation e being close to 0 value and the deviation change rate ec tending to be large or small, the proportion of adjusting e being the smallest and that of ec being the largest; when the deviation rate ec being close to 0 value and the deviation e being large or small, adjusting the proportion of e to the maximum to achieve the purpose of adaptive adjustment.

2. The resilience enhanced simulation method for container logistics supply chain system based on adaptive fuzzy double feedback according to claim 1, wherein:
setting the average waiting time T_{WAIT} as 3˜24 cycles, setting the rated value of T_{WAIT} as 6 cycles; setting the FCPR adjustment time constant T_{FCPR} as 2˜16 cycles, setting the rated value of T_{FCPR} as 4 cycles; setting an average container port handling time T_{P} as 2˜6 cycles, setting the rated value of T_{P} as 4 cycles; setting the desired pretreatment period E as 1; setting a container handling forecasting requirement time constant T_{A}=6, T_{Q}=T_{P}=4; setting an allocation delay time T_{P1} as 0.5˜2 cycles, setting a rated value of T_{P1} as 1 cycle; simulating an influence of time constants T_{WAIT} and T_{FCPR} in the container pretreatment system on the response UCHR, CHIP and PCHR and resilience of the two-subsystem container logistics supply chain system, and analyzing of two-dimensional mechanism of resilience R;
setting UCHR and R as a response performance and resilience performance of the two-subsystem container logistics supply chain system, and T_{WAIT} as a main variable of the supply chain system; after setting the above parameters, simulating and verifying an effectiveness of the resilience-enhancement control method of the container logistics supply chain based on adaptive fuzzy double feedback in increasing UCHR stability and shortening UCHR stability time, obtaining the action mechanism of affordability and recovery ability on resilience under the resilience-enhancement control method of container logistics supply chain based on adaptive fuzzy double feedback;
T_{A}, T_{P}, T_{Q}, E, T_{P1}, T_{WAIT}, T_{FCPR}, T_{CHIP}, T_{UCHR} all being positive numbers.
